(19) United States
(12) Patent Application Publication
(10) Pub. No.: US 2025/0202464 A1
(43) Pub. Date: Jun. 19, 2025

(54) METHODS AND DEVICES FOR PHASE MODULATION IN DIGITAL TRANSMISSION ARCHITECTURE

(71) Applicant: Intel Corporation, Santa Clara, CA (US)

(72) Inventors: Ali AZAM, Beaverton, OR (US); Karthik NATARAJAN, Portland, OR (US); Yishai EILAT, Alonei Abba (IL)

(21) Appl. No.: 18/540,957

(22) Filed: Dec. 15, 2023

(51) Int. Cl. H03K 5/131; H03F 3/24; H03K 5/00

(52) U.S. Cl. CPC H03K 5/131; H03F 3/245; H03K 2005/00078

(57) ABSTRACT

An apparatus may include: a first edge interpolator stage including: a first edge interpolator configured to interpolate, based on a phase modulation code, a first and second signal to generate a first edge interpolated signal comprising a first edge in a time domain between edges of the first and second signal; a second edge interpolator configured to interpolate, based on the phase modulation code, the first and second signal to generate a second edge interpolated signal comprising a second edge in the time domain between edges of the first and second signal; and a second edge interpolator stage configured to: receive the first edge interpolated signal and the second edge interpolated signal; and generate, based on the phase modulation code, a third edge interpolated signal comprising a third edge in the time domain between the edges of the first edge interpolated signal and the second edge interpolated signal.

### TECHNICAL FIELD

This disclosure generally relates to methods and devices for phase modulation in a digital transmission architecture.

### BACKGROUND

The Digital Transmit (DTX) architecture represents a paradigm shift from traditional analog TX architectures, offering enhanced integration and efficiency in wireless communication systems. DTX architectures leverage digital signal processing techniques, enabling compact designs and scalability in advanced CMOS processes, addressing the escalating demands for wider bandwidths and higher modulation schemes. Unlike analog TX architectures, such as Quadrature Analog TX (Q-ATX) systems, which utilize Class-AB CMOS power amplifiers (PAs) and quadrature modulation, DTX architectures rely on digital signal manipulation, enabling improved power efficiency through switching PAs and compact die area.

Many DTX architectures, such as the Digital Polar Transmitter (DPTX) architecture, may include two primary functional blocks: A Digital-to-Time Converter (DTC) and a Digital Power Amplifier (DPA). The DTC may utilize phase information to modulate a local oscillator (LO) signal, while the DPA may modulate the amplitude of the signal onto the phase-modulated LO (MOLO) signal to generate a radio frequency (RF) communication signal.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIG. 1 shows an exemplary radio communication network;

FIG. 2 shows an exemplary internal configuration of a communication device;

FIG. 3 shows an exemplary illustration of various communication elements of an apparatus for a wireless communication device;

FIG. 4 shows an exemplary illustration of a transmit path of an RF transceiver of a communication device;

FIG. 5 shows an exemplary illustration of an edge interpolator including unit cells;

FIG. 6 shows an exemplary graph showing edge-relationship of signals associated with an edge interpolator;

FIG. 7 shows an exemplary schematic illustration of an apparatus in accordance with various aspects of this disclosure;

FIG. 8A shows an exemplary schematic illustration of an apparatus in accordance with various aspects of this disclosure;

FIG. 8B shows an exemplary schematic illustration of a last stage of an apparatus in accordance with various aspects of this disclosure;

FIG. 9A shows an exemplary illustration of edges of signals associated with an apparatus including three edge interpolator stages;

FIG. 9B shows an exemplary illustration of a stage of an apparatus including multiple edge interpolator stages;

FIG. 10 shows an exemplary graph of a cadence spectre transient simulation for first stage input and output waveshapes;

FIG. 11 shows an exemplary graph of a cadence spectre transient simulation for second stage input and output waveshapes;

FIG. 12 shows exemplary graph of a cadence spectre transient simulation for second stage input and output waveshapes;

FIG. 13 shows an exemplary graph of a cadence spectre transient simulation for third stage input waveshapes;

FIG. 14 shows an exemplary graph of a cadence spectre transient simulation for third stage output waveshapes;

FIG. 15 shows an example of a graph showing simulation results;

FIG. 16 shows an example of a method.

### DESCRIPTION

The following detailed description refers to the accompanying drawings that show, by way of illustration, exemplary details and aspects in which aspects of the present disclosure may be practiced.

In recent RF communication architectures, radio communication apparatus and devices may include components to support RF operation in multiple frequency bands to leverage various services and applications. Traditionally, such devices utilize a distinct power amplifier and possibly further components or modules for each designated frequency band, in order to operate within desired or designated characteristics for RF communication. Exemplarily, a Wireless Fidelity (Wi-Fi) communication apparatus may include first one or more DPAs for RF operations according to 2.4 GHz band, second one or more DPAs for RF operations according to 5 GHz band, and third one or more DPAs for RF operations according to 6 GHz band. Such an approach may contribute to an increased complexity, die area, form factor, and subsequently, cost. Moreover, as wireless communication technology now commonly supports mechanisms having an increased complexity than earlier systems, such as Multiple-Input Multiple-Output (MIMO) and carrier aggregation (CA) techniques, the demand of bandwidth for RF operations grows.

It is to be noted herein, the term “DPA” used herein may refer to circuitry that is configured to receive an input digital signal and to provide an output signal at a desired power level for RF transmission in a DTX architecture by referencing to DPAs replacing analog PAs. Such circuitry may be referred to as a Digital to Power Converter (DPC) and may include a CDAC to convert the received input digital signal to the output signal, pointing to its aspects associated with conversion of DC energy to AC through controlled capacitive divider. CDACs may be referred to as capacitive RF digital to analog converters (RF-CDACs) or switched-capacitor RF-DACs.

A DTC is another crucial component within DTX architectures, particularly in systems aiming for high-efficiency modulation techniques. The primary function of a DTC may include converting digital information into precise timing signals or time intervals. In some examples, rather than directly manipulating voltage or current levels as in traditional analog systems, a DTC may operate by generating time-based representations of digital signals. A DTC may translate digital bits into specific time durations or intervals, where these intervals may determine the timing of signal transitions.

In a TX system, the DTC may modulate the timing of signals, often using techniques like phase modulation or pulse width modulation. It may take digital input data and encodes received digital input data into timing intervals, which may then be used to control various aspects of the signal transmitted by the transmitter, such as phase or pulse width. This precise manipulation of time intervals may enable the transmission of digital information in the form of modulated signals to achieve efficient and accurate communication. Exemplarily, in a Digital Polar TX architecture or an In-phase Quadrature-phase signal (IQ) based mmWave Transmitter architecture, the DTC may perform phase modulation (RF) or multi-phase generation (mmWave), which may require the operation of the DTC with a high-resolution. Referring to mmWave applications, the DTC may generate multiple phases at a lower frequency which may be required as inputs to an injection locked oscillator to generate precise IQ phases for the mmWave transmitter.

In some aspects, a DTC may include binary and/or thermo-metric sized inverters that may be configured to perform edge interpolation to generate precise phase differences between IQ signals. An edge interpolator may include an array of inverters including a number of inverters used to manipulate a received first (e.g. in-phase) signal and a number of inverters used to manipulate a received second (e.g. quadrature phase) signal to provide an output signal with phase difference depending on the phase difference between the received first and second signals and the number of inverters respectively used. It may be desirable to use minimum sized inverters for minimizing switching loss associated with the operation of the edge interpolator.

In some aspects, the edge interpolator may include a binary edge interpolator array (i.e. an edge interpolator array controllable with a binary input) including minimum sized inverters, which may consequently prohibit a thermometric edge interpolator array (i.e. an edge interpolator array controllable with a thermometric input) to be minimum sized, which may result in a higher operating power. In some aspects, the edge interpolator may include a thermometric edge interpolator array, which may result in the binary edge interpolator array to be series stacked devices that may introduce non-linearities in the system as the binary edge interpolator array may not have the same slope as the thermometric edge interpolator array.

It is further to be noted that the phase difference generation may include a first introduced coarse phase difference followed by a second introduced fine phase difference. Therefore, increasing the number of unit cells (e.g. inverters) to achieve a desired resolution of the controllable phase difference (i.e. desired time steps increases at first and/or second input signals may increase the overall inter-stage buffer consumption. As for each additional bit introduced to describe a finer resolution, such problems may aggravate by a factor of 2. Moreover, the overall size of the decoder that may convert phase data (e.g. phase modulation code) to digital bits to be fed to the DTC may double in size with each additional bit to describe a finer resolution.

In more detail, an edge-interpolation based DTC may provide the best figure-of-merit in terms achievable linearity, area and power consumption and scalability. Since it is a ratio-metric operation, the operation is much robust against process, voltage and temperature (PVT) variation. A digitally controlled edge interpolator (DCEI) may include a thermometric most significant bit (MSB) array including of an equal number of inverter unit cells and a binary least significant bit (LSB) array including a binary sized array. Since the thermometric array already may utilize lowest available inverter size, usually binary array may include stacking devices to create higher on resistance which effectively work similar to a scaled down sized inverter. Therefore, each binary bit utilizes two-times more stacked devices compared to previous binary bit; which is problematic for scalability.

In accordance with various aspects described herein, an apparatus (e.g. an apparatus of a DTC) may include multiple edge interpolator stages connected in a series configuration, such that a second stage may receive its input signals from a first stage, if available a third stage may receive its input signals from the second stage, and so on. Each intermediate stage of the multiple stages may compare a first phase difference and a second phase difference created by a previous stage and provide output signals each having a different phase difference between the first phase difference and the second phase difference. The initial stage may receive a generated signal with a designated phase difference and provide output signals each having a different phase difference and the end stage may also compare a first phase difference and a second phase difference created by its previous stage and provide an output including signal with a desired phase difference. Each stage may include thermometric arrays, binary arrays or a combination of binary and thermometric arrays.

With the series-stage configuration described above, the apparatus may achieve a finer resolution can be achieved even using solely thermometric arrays while the number of inverters within each array may also be reduced compared to conventional methods, which may result in a reduction of power consumption by the DTC. Furthermore, the complexity and size of physical implementation may decrease. Furthermore, as the fine interpolation is divided into multiple stages, the apparatus may include no or fewer inter-stage buffers in comparison with the conventional applications.

In accordance with various aspects described herein, each stage may include a first edge interpolator and a second edge interpolator. The first edge interpolator and the second edge interpolator may be configured such that the phase output of each stage is rotatable but with a designated phase difference. In other words, each edge interpolator within a stage may be configured such that while the first edge interpolator provides a first output including first output signal with a first phase difference relative to input signals and the second edge interpolator provides a second output including a second output signal with a second phase difference relative to input signals. Illustratively, the second phase difference may be configured based on the first phase difference and noting that both the first edge interpolator and the second edge interpolator may receive the same input signals, output of the first edge interpolator and the second edge interpolator may result in a rotatable but a fixed phase difference relative to each other for the next stage.

In accordance with various aspects provided herein, each stage of the plurality of stages of an apparatus may be configured to operate with a portion of a phase-modulation code generated to indicate a designated phase difference. Illustratively, the first stage of the plurality of stages, of which its inputs may be connected to a signal provider (e.g. an oscillator or an earlier phase difference generator between two input signals), the first stage may operate with a first portion of the phase modulation code, in which the first portion includes the MSB of the phase modulation code to provide a coarse phase difference between its output. The last stage of the plurality of stages, which the last stage is configured to provide an output signal including a signal with the designated phase difference (i.e. a phase modulated signal), may operate with a second portion of the phase modulation code, in which the second portion includes the LSB.

A processor may accordingly generate the phase modulation code in multiple portions and provide each respective portion to a respective stage of the plurality of stages. Each stage may be configured to provide an edge interpolated version of input signals according to a designated resolution, which may be defined by the number of interpolators of respective edge interpolators within the stage. Correspondingly, each portion of the phase modulation code for a respective stage may include a number of bits based on the number of interpolators of the edge interpolators within the respective stage.

In accordance with various aspects provided herein, the last stage of the apparatus may include a single edge interpolator instead of a first and a second edge interpolators. Accordingly, a total number of components (e.g. interpolators) used in the apparatus may be reduced. On the other hand, in some examples, the last stage of the apparatus may still include a first and a second edge interpolators, such that one of the first and the second edge interpolators may have a reversed polarity compared to the other for a better linearity and impedance matching through the transmission circuitry. In accordance with various aspects, one or more stages of the plurality of stages may include dummy unit cells (i.e. unit cell structures which are not configured to apply edge interpolations) to match the exact loading.

The apparatuses and methods of this disclosure may utilize or be related to radio communication technologies. While some examples may refer to specific radio communication technologies, the examples provided herein may be similarly applied to various other radio communication technologies, both existing and not yet formulated, particularly in cases where such radio communication technologies share similar features as disclosed regarding the following examples. Various exemplary radio communication technologies that the apparatuses and methods described herein may utilize include, but are not limited to: a Global System for Mobile Communications (“GSM”) radio communication technology, a General Packet Radio Service (“GPRS”) radio communication technology, an Enhanced Data Rates for GSM Evolution (“EDGE”) radio communication technology, and/or a Third Generation Partnership Project (“3GPP”) radio communication technology, for example Universal Mobile Telecommunications System (“UMTS”), Freedom of Multimedia Access (“FOMA”), 3GPP Long Term Evolution (“LTE”), 3GPP Long Term Evolution Advanced (“LTE Advanced”), Code division multiple access 2000 (“CDMA2000”), Cellular Digital Packet Data (“CDPD”), Mobitex, Third Generation (3G), Circuit Switched Data (“CSD”), High-Speed Circuit-Switched Data (“HSCSD”), Universal Mobile Telecommunications System (“Third Generation”) (“UMTS (3G)”), Wideband Code Division Multiple Access (Universal Mobile Telecommunications System) (“W-CDMA (UMTS)”), High Speed Packet Access (“HSPA”), High-Speed Downlink Packet Access (“HSDPA”), High-Speed Uplink Packet Access (“HSUPA”), High Speed Packet Access Plus (“HSPA+”), Universal Mobile Telecommunications System-Time-Division Duplex (“UMTS-TDD”), Time Division-Code Division Multiple Access (“TD-CDMA”), Time Division-Synchronous Code Division Multiple Access (“TD-CDMA”), 3rd Generation Partnership Project Release 8 (Pre-4th Generation) (“3GPP Rel. 8 (Pre-4G)”), 3GPP Rel. 9 (3rd Generation Partnership Project Release 9), 3GPP Rel. 10 (3rd Generation Partnership Project Release 10), 3GPP Rel. 11 (3rd Generation Partnership Project Release 11), 3GPP Rel. 12 (3rd Generation Partnership Project Release 12), 3GPP Rel. 13 (3rd Generation Partnership Project Release 13), 3GPP Rel. 14 (3rd Generation Partnership Project Release 14), 3GPP Rel. 15 (3rd Generation Partnership Project Release 15), 3GPP Rel. 16 (3rd Generation Partnership Project Release 16), 3GPP Rel. 17 (3rd Generation Partnership Project Release 17), 3GPP Rel. 18 (3rd Generation Partnership Project Release 18), 3GPP 4G, 3GPP LTE Extra, LTE-Advanced Pro, LTE Licensed-Assisted Access (“LAA”), MuLTEfire, UMTS Terrestrial Radio Access (“UTRA”), Evolved UMTS Terrestrial Radio Access (“E-UTRA”), Long Term Evolution Advanced (4th Generation) (“LTE Advanced (4G)”), cdmaOne (“2G”), Code division multiple access 2000 (Third generation) (“CDMA2000 (3G)”), Evolution-Data Optimized or Evolution-Data Only (“EV-DO”), Advanced Mobile Phone System (1st Generation) (“AMPS (1G)”), Total Access Communication arrangement/Extended Total Access Communication arrangement (“TACS/ETACS”), Digital AMPS (2nd Generation) (“D-AMPS (2G)”), Push-to-talk (“PTT”), Mobile Telephone System (“MTS”), Improved Mobile Telephone System (“IMTS”), Advanced Mobile Telephone System (“AMTS”), OLT (Norwegian for Offentlig Landmobil Telefoni, Public Land Mobile Telephony), MTD (Swedish abbreviation for Mobiltelefonisystem D, or Mobile telephony system D), Public Automated Land Mobile (“Autotel/PALM”), ARP (Finnish for Autoradiopuhelin, “car radio phone”), NMT (Nordic Mobile Telephony), High capacity version of NTT (Nippon Telegraph and Telephone) (“Hicap”), Cellular Digital Packet Data (“CDPD”), Mobitex, DataTAC, Integrated Digital Enhanced Network (“iDEN”), Personal Digital Cellular (“PDC”), Circuit Switched Data (“CSD”), Personal Handy-phone System (“PHS”), Wideband Integrated Digital Enhanced Network (“WiDEN”), iBurst, Unlicensed Mobile Access (“UMA”), also referred to as also referred to as 3GPP Generic Access Network, or GAN standard), Zigbee, Bluetooth®, Wireless Gigabit Alliance (“WiGig”) standard, mmWave standards in general (wireless systems operating at 10-300 GHz and above such as WiGig, IEEE 802.11ad, IEEE 802.11ay, etc.), technologies operating above 300 GHz and THz bands, (3GPP/LTE based or IEEE 802.11p and other) Vehicle-to-Vehicle (“V2V”) and Vehicle-to-X (“V2X”) and Vehicle-to-Infrastructure (“V2I”) and Infrastructure-to-Vehicle (“I2V”) communication technologies, 3GPP cellular V2X, DSRC (Dedicated Short Range Communications) communication arrangements such as Intelligent-Transport-Systems, and other existing, developing, or future radio communication technologies.

The apparatuses and methods described herein may use such radio communication technologies according to various spectrum management schemes, including, but not limited to, dedicated licensed spectrum, unlicensed spectrum, (licensed) shared spectrum (such as LSA=Licensed Shared Access in 2.3-2.4 GHz, 3.4-3.6 GHz, 3.6-3.8 GHz and further frequencies and SAS=Spectrum Access System in 3.55-3.7 GHz and further frequencies), and may use various spectrum bands including, but not limited to, IMT (International Mobile Telecommunications) spectrum (including 450-470 MHz, 690-960 MHz, 1710-2025 MHz, 2110-2200 MHz, 2300-2400 MHz, 2500-2690 MHz, 698-790 MHz, 610-790 MHz, 3400-3600 MHz, etc., where some bands may be limited to specific region(s) and/or countries), IMT-advanced spectrum, IMT-2020 spectrum (expected to include 3600-3800 MHz, 3.5 GHz bands, 600 MHz bands, bands within the 24.25-86 GHz range, etc.), spectrum made available under FCC's “Spectrum Frontier” 4G initiative (including 27.5-28.35 GHz, 29.1-29.25 GHz, 31-31.3 GHz, 37-38.6 GHz, 38.6-40 GHz, 42-42.5 GHZ, 47-64 GHz, 64-71 GHz, 61-76 GHz, 81-86 GHz and 92-94 GHz, etc.), the ITS (Intelligent Transport Systems) band of 4.9 GHz (typically 4.85-5.925 GHz) and 63-64 GHz, bands currently allocated to WiGig such as WiGig Band 1 (57.24-59.40 GHz), WiGig Band 2 (59.40-61.56 GHz) and WiGig Band 3 (61.56-63.72 GHz) and WiGig Band 4 (63.72-65.88 GHz), the 60.2 GHz-71 GHz band, any band between 65.88 GHz and 61 GHz, bands currently allocated to automotive radar applications such as 66-81 GHz, and future bands including 94-300 GHz and above. Furthermore, the apparatuses and methods described herein can also employ radio communication technologies on a secondary basis on bands such as the TV White Space bands (typically below 690 MHz) where e.g. the 400 MHz and 600 MHz bands are prospective candidates. Besides cellular applications, specific applications for vertical markets may be addressed such as PMSE (Program Making and Special Events), medical, health, surgery, automotive, low-latency, drones, etc. applications. Furthermore, the apparatuses and methods described herein may also use radio communication technologies with a hierarchical application, such as by introducing a hierarchical prioritization of usage for different types of users (e.g., low/medium/high priority, etc.), based on a prioritized access to the spectrum e.g., with highest priority to tier-1 users, followed by tier-2, then tier-3, etc. users, etc. The apparatuses and methods described herein can also use radio communication technologies with different Single Carrier or OFDM flavors (CP-OFDM, SC-FDMA, SC-OFDM, filter bank-based multicarrier (FBMC), OFDMA, etc.) and e.g. 3GPP NR (New Radio), which can include allocating the OFDM carrier data bit vectors to the corresponding symbol resources.

For purposes of this disclosure, radio communication technologies may be classified as one of a Short Range radio communication technology or Cellular Wide Area radio communication technology. Short Range radio communication technologies may include Bluetooth, WLAN (e.g., according to any IEEE 802.11 standard), and other similar radio communication technologies. Cellular Wide Area radio communication technologies may include Global System for Mobile Communications (“GSM”), Code Division Multiple Access 2000 (“CDMA2000”), Universal Mobile Telecommunications System (“UMTS”), Long Term Evolution (“LTE”), General Packet Radio Service (“GPRS”), Evolution-Data Optimized (“EV-DO”), Enhanced Data Rates for GSM Evolution (“EDGE”), High Speed Packet Access (HSPA; including High Speed Downlink Packet Access (“HSDPA”), High Speed Uplink Packet Access (“HSUPA”), HSDPA Plus (“HSDPA+”), and HSUPA Plus (“HSUPA+”)), Worldwide Interoperability for Microwave Access (“WiMax”) (e.g., according to an IEEE 802.16 radio communication standard, e.g., WiMax fixed or WiMax mobile), etc., and other similar radio communication technologies. Cellular Wide Area radio communication technologies also include “small cells” of such technologies, such as microcells, femtocells, and picocells. Cellular Wide Area radio communication technologies may be generally referred to herein as “cellular” communication technologies.

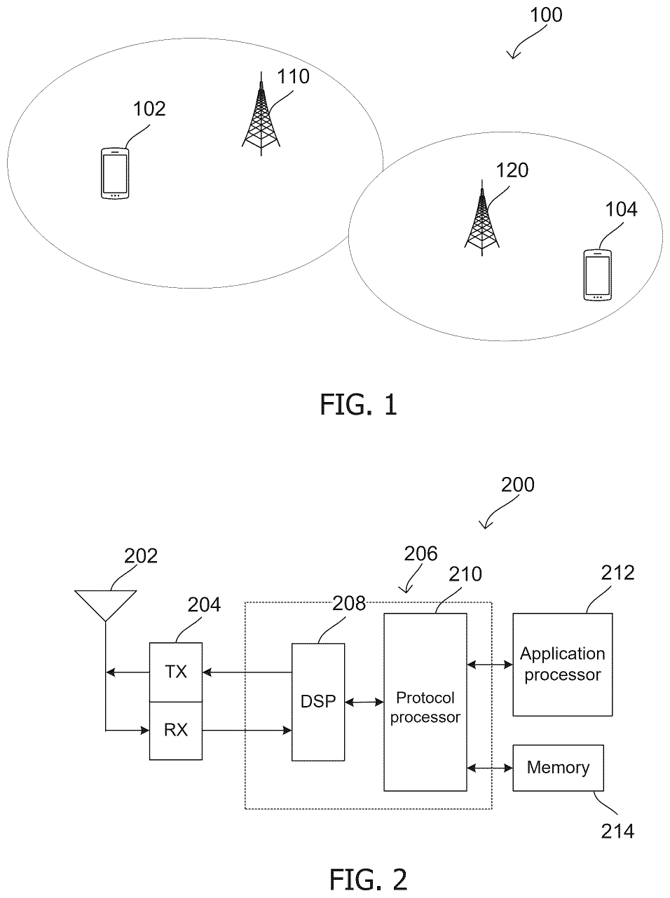

FIGS. 1 and 2 depict a general network and device architecture for wireless communications. In particular, FIG. 1 shows exemplary radio communication network 100 according to some aspects, which may include terminal devices 102 and 104 and network access nodes 110 and 120. Radio communication network 100 may communicate with terminal devices 102 and 104 (i.e. mobile radio communication devices) via network access nodes 110 and 120 (i.e. radio communication devices) over a radio access network. Although certain examples described herein may refer to a particular radio access network context (e.g., LTE, UMTS, GSM, other 3rd Generation Partnership Project (3GPP) networks, WLAN/WiFi, Bluetooth, 4G NR, mmWave, etc.), these examples are demonstrative and may therefore be readily applied to any other type or configuration of radio access network. The number of network access nodes and terminal devices in radio communication network 100 is exemplary and is scalable to any amount.

In an exemplary cellular context, network access nodes 110 and 120 may be base stations (e.g., eNodeBs, NodeBs, Base Transceiver Stations (BTSs), gNodeBs, or any other type of base station), while terminal devices 102 and 104 may be cellular terminal devices (e.g., Mobile Stations (MSs), User Equipments (UEs), or any type of cellular terminal device). Network access nodes 110 and 120 may therefore interface (e.g., via backhaul interfaces) with a cellular core network such as an Evolved Packet Core (EPC, for LTE), Core Network (CN, for UMTS), or other cellular core networks, which may also be considered part of radio communication network 100. The cellular core network may interface with one or more external data networks. In an exemplary short-range context, network access node 110 and 120 may be access points (APs, e.g., WLAN or WiFi APs), while terminal device 102 and 104 may be short range terminal devices (e.g., stations (STAs)). Network access nodes 110 and 120 may interface (e.g., via an internal or external router) with one or more external data networks. Network access nodes 110 and 120 and terminal devices 102 and 104 may include one or multiple transmission/reception points (TRPs).

Network access nodes 110 and 120 (and, optionally, other network access nodes of radio communication network 100 not explicitly shown in FIG. 1) may accordingly provide a radio access network to terminal devices 102 and 104 (and, optionally, other terminal devices of radio communication network 100 not explicitly shown in FIG. 1). In an exemplary cellular context, the radio access network provided by network access nodes 110 and 120 may enable terminal devices 102 and 104 to wirelessly access the core network via radio communications. The core network may provide switching, routing, and transmission, for traffic data related to terminal devices 102 and 104, and may further provide access to various internal data networks (e.g., control nodes, routing nodes that transfer information between other terminal devices on radio communication network 100, etc.) and external data networks (e.g., data networks providing voice, text, multimedia (audio, video, image), and other Internet and application data). In an exemplary short-range context, the radio access network provided by network access nodes 110 and 120 may provide access to internal data networks (e.g., for transferring data between terminal devices connected to radio communication network 100) and external data networks (e.g., data networks providing voice, text, multimedia (audio, video, image), and other Internet and application data).

The radio access network and core network (if applicable, such as for a cellular context) of radio communication network 100 may be governed by communication protocols that can vary depending on the specifics of radio communication network 100. Such communication protocols may define the scheduling, formatting, and routing of both user and control data traffic through radio communication network 100, which includes the transmission and reception of such data through both the radio access and core network domains of radio communication network 100. Accordingly, terminal devices 102 and 104 and network access nodes 110 and 120 may follow the defined communication protocols to transmit and receive data over the radio access network domain of radio communication network 100, while the core network may follow the defined communication protocols to route data within and outside of the core network. Exemplary communication protocols include LTE, UMTS, GSM, WiMAX, Bluetooth, WiFi, mm Wave, etc., any of which may be applicable to radio communication network 100. In accordance with aspects described herein, a network access node 110, 120 or a terminal device 102, 104 may implement aspects described herein (e.g. selection of MIMO detection algorithms, determination of a class for a condition number of a channel matrix, and/or determination a diagonal dominance of a gram matrix and/or spatial covariance matrix).

FIG. 2 shows an exemplary internal configuration of a communication device according to various aspects provided in this disclosure. The communication device may include various aspects of radio communication devices (e.g. network access nodes 110, 120) or various aspects of mobile radio communication devices (e.g. terminal device 102, 104) as well. The communication device 200 may include antenna system 202, radio frequency (RF) transceiver 204, baseband modem 206 (including digital signal processor 208 and protocol controller 210), application processor 212, and memory 214. Although not explicitly shown in FIG. 2, in some aspects communication device 200 may include one or more additional hardware and/or software components, such as processors/microprocessors, controllers/microcontrollers, other specialty or generic hardware/processors/circuits, peripheral device(s), memory, power supply, external device interface(s), subscriber identity module(s) (SIMs), user input/output devices (display(s), keypad(s), touchscreen(s), speaker(s), external button(s), camera(s), microphone(s), etc.), or other related components.

Communication device 200 may transmit and receive radio signals on one or more radio access networks. Baseband modem 206 may direct such communication functionality of communication device 200 according to the communication protocols associated with each radio access network, and may execute control over antenna system 202 and RF transceiver 204 to transmit and receive radio signals according to the formatting and scheduling parameters defined by each communication protocol. Although various practical designs may include separate communication components for each supported radio communication technology (e.g., a separate antenna, RF transceiver, digital signal processor, and controller), for purposes of conciseness the configuration of communication device 200 shown in FIG. 2 depicts only a single instance of such components.

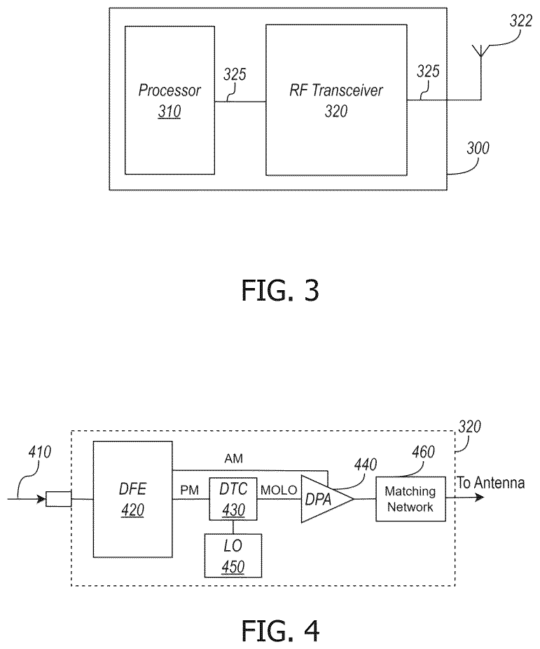

Communication device 200 may transmit and receive wireless signals with antenna system 202. Antenna system 202 may be a single antenna or may include one or more antenna arrays that each include multiple antenna elements. For example, antenna system 202 may include an antenna array at the top of communication device 200 and a second antenna array at the bottom of communication device 200. In some aspects, antenna system 202 may additionally include analog antenna combination and/or beamforming circuitry. In the receive (RX) path, RF transceiver 204 may receive analog radio frequency signals from antenna system 202 and perform analog and digital RF front-end processing on the analog radio frequency signals to produce digital baseband samples (e.g., In-Phase/Quadrature (IQ) samples) to provide to baseband modem 206. RF transceiver 204 may include analog and digital reception components including amplifiers (e.g., Low Noise Amplifiers (LNAs)), filters, RF demodulators (e.g., RF IQ demodulators)), and analog-to-digital converters (ADCs), which RF transceiver 204 may utilize to convert the received radio frequency signals to digital baseband samples. In the transmit (TX) path, RF transceiver 204 may receive digital baseband samples from baseband modem 206 and perform analog and digital RF front-end processing on the digital baseband samples to produce analog radio frequency signals to provide to antenna system 202 for wireless transmission. RF transceiver 204 may thus include analog and digital transmission components including amplifiers (e.g., Power Amplifiers (PAS), filters, RF modulators (e.g., RF IQ modulators), and digital-to-analog converters (DACs), which RF transceiver 204 may utilize to mix the digital baseband samples received from baseband modem 206 and produce the analog radio frequency signals for wireless transmission by antenna system 202. In some aspects baseband modem 206 may control the radio transmission and reception of RF transceiver 204, including specifying the transmit and receive radio frequencies for operation of RF transceiver 204. In accordance with various aspects provided herein, the TX path may be configured as described in FIG. 3.

As shown in FIG. 2, baseband modem 206 may include digital signal processor 208, which may perform physical layer (PHY, Layer 1) transmission and reception processing to, in the transmit path as illustrated in FIG. 3, prepare outgoing transmit data provided by protocol controller 210 for transmission via RF transceiver 204, and, in the receive path, prepare incoming received data provided by RF transceiver 204 for processing by protocol controller 210. Digital signal processor 208 may be configured to perform one or more of error detection, forward error correction encoding/decoding, channel coding and interleaving, channel modulation/demodulation, physical channel mapping, radio measurement and search, frequency and time synchronization, antenna diversity processing, power control and weighting, rate matching/de-matching, retransmission processing, interference cancelation, and any other physical layer processing functions. Digital signal processor 208 may be structurally realized as hardware components (e.g., as one or more digitally-configured hardware circuits or FPGAs), software-defined components (e.g., one or more processors configured to execute program code defining arithmetic, control, and I/O instructions (e.g., software and/or firmware) stored in a non-transitory computer-readable storage medium), or as a combination of hardware and software components. In some aspects, digital signal processor 208 may include one or more processors configured to retrieve and execute program code that defines control and processing logic for physical layer processing operations. In some aspects, digital signal processor 208 may execute processing functions with software via the execution of executable instructions. In some aspects, digital signal processor 208 may include one or more dedicated hardware circuits (e.g., ASICs, FPGAs, and other hardware) that are digitally configured to specific execute processing functions, where the one or more processors of digital signal processor 208 may offload certain processing tasks to these dedicated hardware circuits, which are known as hardware accelerators. Exemplary hardware accelerators can include Fast Fourier Transform (FFT) circuits and encoder/decoder circuits. In some aspects, the processor and hardware accelerator components of digital signal processor 208 may be realized as a coupled integrated circuit.

Communication device 200 may be configured to operate according to one or more radio communication technologies. Digital signal processor 208 may be responsible for lower-layer processing functions (e.g., Layer 1/PHY) of the radio communication technologies, while protocol controller 210 may be responsible for upper-layer protocol stack functions (e.g., Data Link Layer/Layer 2 and/or Network Layer/Layer 3). Protocol controller 210 may thus be responsible for controlling the radio communication components of communication device 200 (antenna system 202, RF transceiver 204, and digital signal processor 208) in accordance with the communication protocols of each supported radio communication technology, and accordingly may represent the Access Stratum and Non-Access Stratum (NAS) (also encompassing Layer 2 and Layer 3) of each supported radio communication technology. Protocol controller 210 may be structurally embodied as a protocol processor configured to execute protocol stack software (retrieved from a controller memory) and subsequently control the radio communication components of communication device 200 to transmit and receive communication signals in accordance with the corresponding protocol stack control logic defined in the protocol software. Protocol controller 210 may include one or more processors configured to retrieve and execute program code that defines the upper-layer protocol stack logic for one or more radio communication technologies, which can include Data Link Layer/Layer 2 and Network Layer/Layer 3 functions. Protocol controller 210 may be configured to perform both user-plane and control-plane functions to facilitate the transfer of application layer data to and from radio communication device 200 according to the specific protocols of the supported radio communication technology. User-plane functions can include header compression and encapsulation, security, error checking and correction, channel multiplexing, scheduling and priority, while control-plane functions may include setup and maintenance of radio bearers. The program code retrieved and executed by protocol controller 210 may include executable instructions that define the logic of such functions.

Communication device 200 may also include application processor 212 and memory 214. Application processor 212 may be a CPU, and may be configured to handle the layers above the protocol stack, including the transport and application layers. Application processor 212 may be configured to execute various applications and/or programs of communication device 200 at an application layer of communication device 200, such as an operating system (OS), a user interface (UI) for supporting user interaction with communication device 200, and/or various user applications. The application processor may interface with baseband modem 206 and act as a source (in the transmit path) and a sink (in the receive path) for user data, such as voice data, audio/video/image data, messaging data, application data, basic Internet/web access data, etc. In the transmit path, protocol controller 210 may therefore receive and process outgoing data provided by application processor 212 according to the layer-specific functions of the protocol stack, and provide the resulting data to digital signal processor 208. Digital signal processor 208 may then perform physical layer processing on the received data to produce digital baseband samples, which digital signal processor may provide to RF transceiver 204. RF transceiver 204 may then process the digital baseband samples to convert the digital baseband samples to analog RF signals, which RF transceiver 204 may wirelessly transmit via antenna system 202. In the receive path, RF transceiver 204 may receive analog RF signals from antenna system 202 and process the analog RF signals to obtain digital baseband samples. RF transceiver 204 may provide the digital baseband samples to digital signal processor 208, which may perform physical layer processing on the digital baseband samples. Digital signal processor 208 may then provide the resulting data to protocol controller 210, which may process the resulting data according to the layer-specific functions of the protocol stack and provide the resulting incoming data to application processor 212. Application processor 212 may then handle the incoming data at the application layer, which can include execution of one or more application programs with the data and/or presentation of the data to a user via a user interface.

Memory 214 may embody a memory component of communication device 200, such as a hard drive or another such permanent memory device. Although not explicitly depicted in FIG. 2, the various other components of communication device 200 shown in FIG. 2 may additionally each include integrated permanent and non-permanent memory components, such as for storing software program code, buffering data, etc.

In accordance with various aspects provided herein, at least one of baseband modem 206 or application processor 212 may perform operations described in this disclosure by referring to “processor”.

In accordance with some radio communication networks, terminal devices 102 and 104 may execute mobility procedures to connect to, disconnect from, and switch between available network access nodes of the radio access network of radio communication network 100. As each network access node of radio communication network 100 may have a specific coverage area, terminal devices 102 and 104 may be configured to select and re-select\ available network access nodes in order to maintain a strong radio access connection with the radio access network of radio communication network 100. For example, terminal device 102 may establish a radio access connection with network access node 110 while terminal device 104 may establish a radio access connection with network access node 112. In the event that the current radio access connection degrades, terminal devices 102 or 104 may seek a new radio access connection with another network access node of radio communication network 100; for example, terminal device 104 may move from the coverage area of network access node 112 into the coverage area of network access node 110. As a result, the radio access connection with network access node 112 may degrade, which terminal device 104 may detect via radio measurements such as signal strength or signal quality measurements of network access node 112. Depending on the mobility procedures defined in the appropriate network protocols for radio communication network 100, terminal device 104 may seek a new radio access connection (which may be, for example, triggered at terminal device 104 or by the radio access network), such as by performing radio measurements on neighboring network access nodes to determine whether any neighboring network access nodes can provide a suitable radio access connection. As terminal device 104 may have moved into the coverage area of network access node 110, terminal device 104 may identify network access node 110 (which may be selected by terminal device 104 or selected by the radio access network) and transfer to a new radio access connection with network access node 110. Such mobility procedures, including radio measurements, cell selection/reselection, and handover are established in the various network protocols and may be employed by terminal devices and the radio access network in order to maintain strong radio access connections between each terminal device and the radio access network across any number of different radio access network scenarios.

FIG. 3 shows an exemplary illustration of various communication elements of an apparatus for a wireless communication device (e.g. the communication device 200). The apparatus 300 may include processing circuitry 310 (e.g. the baseband modem 206, the application processor 212) that may direct and manage communication operations of the apparatus 300 according to one or more radio communication protocols, and may control transmission/reception of communication signals over at least one or more antenna 322 via an RF transceiver 320. The processing circuitry 310 may include an interface to the RF transceiver 320. The RF transceiver 320 may include at least one RF-chain to process the communication signals associated with the antenna 322 respectively. The apparatus 300 may include the antenna 322, or the apparatus 300 may include an antenna interface couplable to the antenna 322. It is to be noted that the apparatus 300 is depicted as being couplable to the antenna 322, but the apparatus 300 may be couplable to a plurality of antennas, and thereby the RF transceiver 320 may include a plurality of RF-chains, each RF-chain may process communication signals for a respective antenna. The apparatus 300 may transmit and receive radio communication signals with the antenna 322. The apparatus 300 may act as an RF transmitter (e.g. RF transmit circuit) to transmit radio communication signals and it may also act as an RF receiver (e.g. RF receive circuit) to receive radio communication signals.

The processing circuitry 310 may include, or may be implemented, partially or entirely, by circuit and/or logic, e.g., a processor including circuit and/or logic, a memory circuit and/or a logic, which may be configured to manage radio communication operations. The processing circuitry 310 may be configured to communicate with an external main processor (e.g. a host processor, a central processing unit (CPU), a system on chip (SoC)) of the wireless communication device including the apparatus 300 via a designated interface that is coupled to the main processor. In some examples, the processing circuitry 310 may be the main processor of the wireless communication device. The processing circuitry 310 may also access the main memory of the respective wireless communication device via the designated interface. The processing circuitry 310 may further include an interface to the RF transceiver 320.

The processing circuitry 310 may include a digital signal processor (e.g. the digital signal processor 208). The digital signal processor 208 may be configured to perform one or more of error detection, forward error correction encoding/decoding, channel coding, and interleaving, channel modulation/demodulation, physical channel mapping, radio measurement and search, frequency and time synchronization, antenna diversity processing, power control, and weighting, rate matching/de-matching, retransmission processing, interference cancelation, and any other physical layer processing functions.

The processing circuitry 310 may include a modem configured to process baseband signals received from/sent to the antenna 322 via a communication path 325 including a respective RF chain. In various examples, the interface to the RF transceiver 320 of the processing circuitry 310 may be configured to couple the processing circuitry 310 to the communication path 325. Accordingly, the processing circuitry 310 may include Media-Access Control (MAC) circuit and/or logic, Physical Layer (PHY) circuit and/or logic, baseband (BB) circuit and/or logic, a BB processor, a BB memory, Application Processor (AP) circuit and/or logic, an AP processor, an AP memory, and/or any other circuit and/or logic. By way of example, the processing circuitry 310 can perform baseband processing on the digital baseband signals to recover data included in wireless data transmissions.

The processing circuitry 310 may control and/or arbitrate transmit and/or receive functions of the apparatus 300, and perform one or more baseband processing functions (e.g., media access control (MAC), encoding/decoding, modulation/demodulation, data symbol mapping, error correction, etc.). The processing circuitry 310 may be configured to provide control functions to the RF transceiver 320 (e.g. to the RF-chain to control and/or arbitrate transmitting and/or receiving radio communication signals). In aspects, functions of processing circuitry 310 can be implemented in software and/or firmware executing on one or more suitable programmable processors, and may be implemented, for example, in a field programmable gate array (FPGA), application specific integrated circuit (ASIC), etc. In various examples, the interface to the RF transceiver 320 of the processing circuitry 310 may be configured to couple processing circuitry to the RF transceiver to provide communication in-between.

The RF transceiver 320 may provide RF processing of communication signals conveyed via a communication path within a respective RF chain to transmit radio communication signals via a respective antenna based on signals (e.g. baseband communication signals, digital signals) received from the processing circuitry 310 over the communication path. The RF transceiver 320 may provide RF processing of communication signals conveyed via the communication path 325 to receive radio communication signals via the antenna 322 and provide signals to the processing circuitry 310 over the communication path 325. The processing circuity 310 may be configured to control operations of the RF transceiver 320. The RF transceiver 320 may include a receive path to provide RF processing to receive radio communication signals received from the antenna 322, and a transmit path to provide RF processing to transmit radio communication signals transmitted via the antenna 322.

In a receive (RX) path, The RF transceiver 320 may receive analog radio frequency signals from the antenna 322 via the communication paths 325 and perform analog and digital RF front-end processing on the analog radio frequency signals to produce digital baseband samples (e.g., In-Phase/Quadrature (IQ) samples) to provide to the processing circuitry 310. In various examples, RF transceiver 320 may include two RF-chains per antenna element, each RF-chain may be designated for a particular polarization. The RF transceiver 320 may include analog and digital reception components including amplifiers (e.g., Low Noise Amplifiers (LNAs)), filters, RF demodulators (e.g., RF IQ demodulators)), and analog-to-digital converters (ADCs), which RF transceiver 320 may utilize to convert the received radio frequency signals to digital baseband samples.

In a transmit (TX) path, the RF transceiver 320 may receive digital baseband samples from processing circuitry 310 and perform analog and digital RF front-end processing on the digital baseband samples to produce analog radio frequency signals to be provided to the antenna 322 via the communication paths 325 for radio transmission. The RF transceiver 320 may thus include analog and digital transmission components including amplifiers (e.g., Power Amplifiers (PAS), filters, RF modulators (e.g., RF IQ modulators), and digital-to-analog converters (DACs), which the RF transceiver 320 may utilize to mix the digital baseband samples received from processing circuitry 310 and produce respective analog radio frequency signals for radio transmission by the antenna 322. In some aspects, the processing circuitry 310 may control the radio transmission and reception of the RF transceiver 320, including specifying the transmit and receive radio frequencies for the operation of the RF transceiver 320. In some examples, the RF transceiver 320 may include a DTX architecture including a DTC described herein. In some examples, operations associated with the digital front-end may be provided by the processing circuitry 310 as well, or in other words, the processing circuitry 310 may include the digital front-end.

FIG. 4 shows an exemplary illustration of a transmit path of an RF transceiver 320 of a communication device (e.g. the communication device 200). The RF transceiver 320, of which the transmit path illustrated herein, may be configured for a digital polar TX. The RF transceiver 320 may be couplable to processing circuitry (e.g. a modem, baseband modem 206, application processor 212) over an interface. The interface may include a communication path designated to carry communication signals between the processing circuitry and an antenna. In some examples, the interface may include a further circuit path to provide communication between the RF transceiver 320 and the processing circuitry for control of the operations. The RF transceiver 320 may further include further components and or circuits, such as further filter circuits, synthesizer circuits, etc. that are not depicted here. The RF transceiver 320 may include various circuits and components deployed on the respective transmission path.

The RF transceiver 320 may include a digital front end (DFE) 320. The DFE 420 may receive the communication signals 410 via the interface coupling the processing circuitry to the DFE 420. The DFE 420 may include a DFE processing circuitry and further components. The DFE may 320 be configured to convert the communication signals 410 (e.g. in-phase/quadrature (IQ) signals) into a polar signal including an amplitude modulation (AM) signal (e.g. amplitude control codes) and a phase modulation (PM) signal (e.g. phase control codes).

In more detail, the DFE 420 may be configured to convert baseband data to AM control codes and PM control codes to be used by the DPA 440 and the DTC 430 respectively to generate RF communication signal to be transmitted from the transmit path. Exemplarily, the DFE 420 may include a modem for modulation/demodulation of signals (e.g. to output IQ data) and a coordinate rotation digital computer (CORDIC) unit configured to perform a series of rotations of the IQ data to calculate the phase and amplitude of the signal. The DFE 420 may accordingly provide the phase control code and the amplitude control code representative of calculated phase and amplitude respectively.

The RF transceiver 320 may further include a digital to time converter (DTC) 430 circuit. The DTC 430 may be coupled to the DFE 420. The DTC 430 may receive the phase modulation signal. The DTC 430 may be further coupled to a local oscillator (LO) 450. The DTC 430 may adjust polar modulation parameters based on the PM signal (e.g. phase control codes) that the DFE 420 provides to generate a modulated signal. By adjusting the polar modulation parameters based on the PM signal, the DTC 430 may output a phase modulated local oscillator (MOLO) signal.

The RF transceiver 320 may further include a digital power amplifier (DPA) 440. The DPA 440 may receive the AM signal (e.g. amplitude control codes) setting desired power of the output of the DPA 440. DPA 440 may further receive the MOLO signal (i.e. output of the DTC 430) and provide an output RF signal based on the received MOLO signal and received AM signal. The DPA 440 may include a DPC, or a CDAC. The DPA 440 may be coupled to a matching network 460 for impedance matching within the transmission chain and for filtering out unwanted frequencies and harmonics.

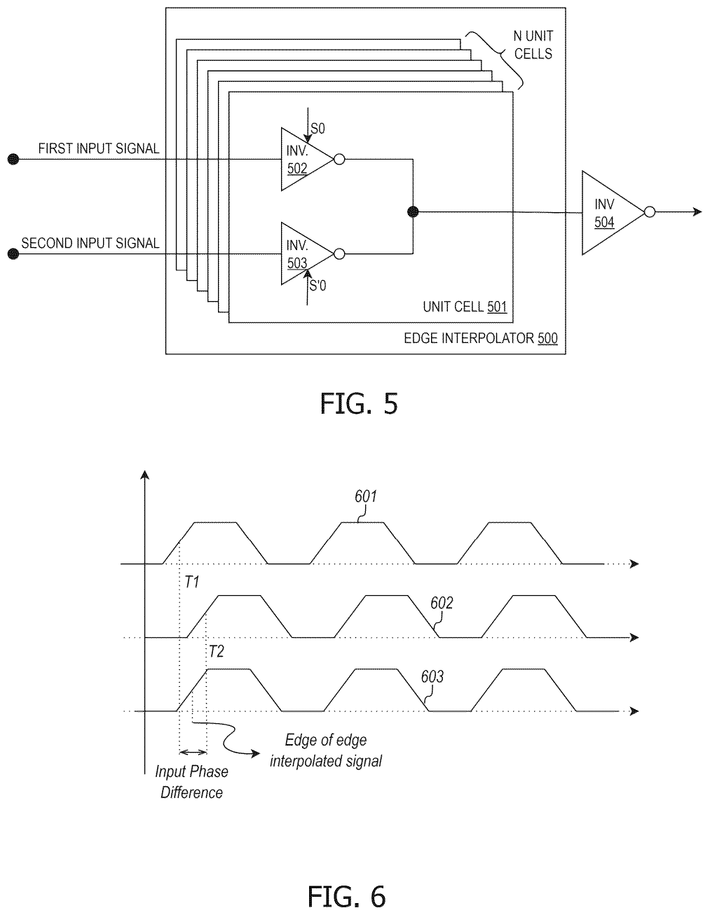

FIG. 5 shows an exemplary illustration of an edge interpolator including unit cells. The edge interpolator 500 may include N unit cells 501, which may also be referred to as an interpolator in this disclosure. N is an integer greater than or equal to two. In particular, N may be based on the number of bits used to control the edge interpolator 500 (e.g. for thermometric approach N+1 unary bits). Each interpolator 501 may include a first inverter 502 and a second inverter 503. Each first inverter 502 may receive a first input signal and each second inverter 503 may receive second input signal. The outputs of the first and second inverters 502, 503 may be coupled to each other to provide an output signal.

Signals S0 and S′0 may control the respective inverter pair of each unit cell 501. Illustratively, a supply circuit may supply each inverter 502, 503 either with a supply voltage or with a zero voltage to allow operation of each unit cell respectively, which control signals are illustrated as S0 and S′0 for the first and second inverters 502, 503 respectively. The supply circuit may be configured in accordance with any known methods to turn on/off operation of each unit cell 501 independently based on received phase modulation codes.

Inputs of all unit cells 501 may be coupled to each other in parallel to receive the same first and second input signals respectively. Similarly, output of each unit cell 501 may be coupled together in parallel to provide an output signal of the edge interpolator 500. In some examples, a buffered inverter 504 may be coupled to the output of the edge interpolator. The first input signal and the second input signal may be equivalent signals having a designated phase difference.

Illustratively, through controlling S0 and S′0 control signals, each unit cell 501 may be responsive to either the first input signal or the second input signal. For example, if all S0 signals provided to the first inverters 502 of the unit cells 501, all unit cells 501 may be responsive to the first input signal (i.e. and unresponsive to the second input signal). If all S′0 signals provided to the second inverters 503 of the unit cells 501, all unit cells may be responsive to the second input signal (i.e. and unresponsive to the first input signal). Through a selection of S0 and S′0 signals in-between, the output signal of the edge interpolator 500 may be an edge interpolated signal, such that the edge interpolated signal has an edge shifted between the corresponding edge of the first input signal and the corresponding edge of the second input signal. Noting that input signals have edges (rising or falling) at time instance of T1 and T2 in time domain having a time difference (which may also be referred to as phase difference) Δ, the output signal would have an edge (rising or falling corresponding to edges of input signal) which is controllable with a resolution of Δ/R, R being an integer based on the number of the unit cells 501. Illustratively, received phase modulation code by the edge interpolator 500 control the location of the corresponding edge of the output signal in the time domain relative to one of the input signals, which may be denoted as T1+C*Δ/R, C being an integer smaller or equal than R. Illustratively, C may correspond to the number of the unit cells 501 that contributes to the time delay provided for the output signal, the provided time delay may be illustratively relative to the first input signal.

As illustrated herein, the edge interpolator 500 may include 2N interpolators 501, each may include the first inverter 502 and the second inverter 503, N being an integer greater than or equal to 2, each interpolator being coupled to same input terminals to receive the first input signal and the second input signal respectively may provide a synchronicity.

FIG. 6 shows an exemplary graph showing edge-relationship of signals associated with an edge interpolator. The first input signal 601 and the second input signal 602 are illustrated herein as input signals of an edge interpolator (e.g. the edge interpolator 500). In implementation, the first input signal 601 and the second input signal 602 may be even and odd signals (which may alternatively be referred to as in-phase and quadrature phase signals, the in-phase signal marking the reference for phase relationship for the quadrature phase signal), in which the second input signal 602 may be a time shifted (e.g. delayed) version of the first input signal 601. An edge of the first input signal 601 may be at T1 in time domain while an edge of the second input signal 602 may be at T2 in time domain, thereby providing a phase difference of A between the input signals.

Accordingly, the output signal 603 of the edge interpolator may have an edge located in the time domain between T1 and T2. Illustratively, for the edge interpolator 500 including 10 unit cells, the resolution of the edge interpolator may be Δ/10, and received phase modulation code may have cause the edge of the output signal 603 to be located at T1+3*Δ/10. In other words, the phase of the edge interpolated signal (e.g. exemplarily relative to the first input signal) would be a fraction of the phase difference between input signals.

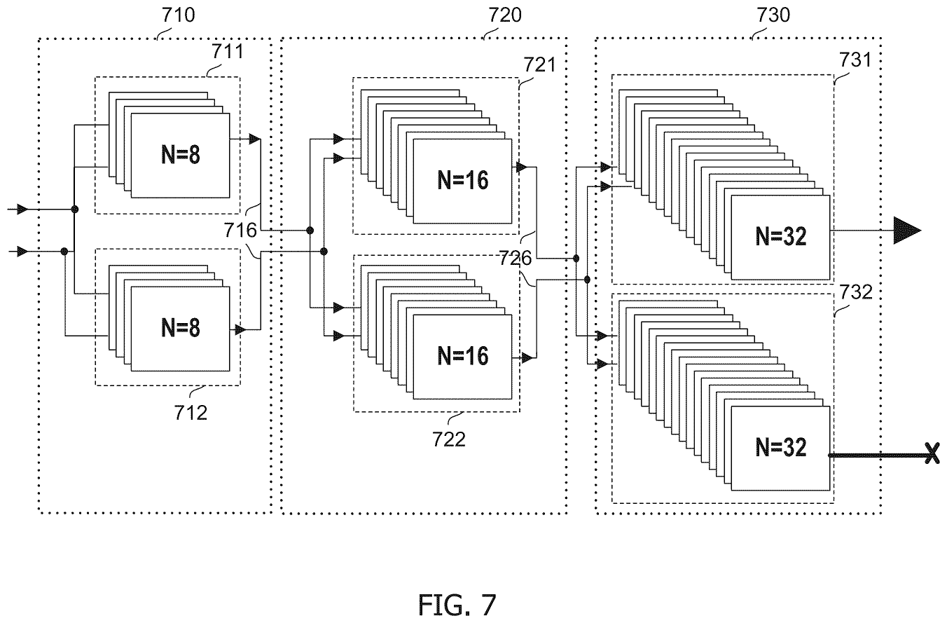

FIG. 7 shows an exemplary schematic illustration of an apparatus in accordance with various aspects of this disclosure. The apparatus may include a plurality of edge interpolator stages (which may be referred to as stages) 710, 720, 730 coupled in a series configuration. Each stage may include a first edge interpolator 711, 721, 731, and a second edge interpolator 712, 722, 732. The first stage 710 may receive input signals (i.e. a first input signal and a second input signal) from an even-odd signal provider, such as an oscillator or another module or component, illustratively of a DTC. The received input signals may have a designated phase difference.

The first stage 710 may output edge interpolated signals 716 having a first phase difference that is a fraction of the designated phase difference. Illustratively, the first edge interpolator 711 may receive the input signals and perform an edge interpolation to the input signals based on a phase modulation code. In this illustration, the first edge interpolator 711 includes 8 unit cells and in a unary configuration, the 8 unit cells may provide 8 resolution steps, providing a configurable interpolation of an edge of an output signal of the first edge interpolator 711 in accordance with C*Δ₁/8, Δ₁ being the time difference between the input signals and C being a selectable integer based on a portion of the phase modulation code associated with the first stage 710. In other words, the first edge interpolator 711 may provide a plurality of time delays (e.g. relative to the first input signal or the second input signal), and each time delay may correspond to a fraction of the time difference between the input signals selected from of a plurality of fractions achievable based on the number of unit cells included in the first edge interpolator. In any event, Δ₁ being the time difference between the input signals, the output signal of the first edge interpolator 711 has a time difference illustratively with the first input signal of a fraction of the designated time difference, the fraction being between 0 and 1.

The second edge interpolator 712 may also receive the input signals and perform an edge interpolation to the input signals based on a phase modulation code. In this illustration, the second edge interpolator 711 also includes 8 unit cells and in a unary configuration, the 8 unit cells may provide 8 resolution steps, providing a configurable interpolation of an edge of an output signal of the second edge interpolator 712 in accordance with C*Δ₁/8, Δ₁ being the time difference between the input signals and C being a selectable integer based on a portion of the phase modulation code associated with the first stage 710. In other words, the second edge interpolator 712 may provide a plurality of time delays (e.g. relative to the first input signal or the second input signal), and each time delay may correspond to a fraction of the time difference between the input signals selected from a plurality of fractions achievable based on the number of unit cells included in the first edge interpolator. In any event, Δ₁ being the time difference between the input signals, the output signal of the second edge interpolator 711 has a time difference illustratively with the first input signal of a fraction of the designated time difference Δ₁, the fraction being between 0 and 1.

In order to obtain, at the output of the first stage 710, edge interpolated signals 716 having a first phase difference Δ₂ that is a fraction of the designated phase difference, the first edge interpolator 711 and the second edge interpolator 712 may obtain two edge interpolated signals 716 of which their respective edges are provided in different locations in the time domain. Illustratively, the first edge interpolator 711 may output a first edge interpolated signal that may include an edge with a time delay (e.g. relative to the first input signal) of Cᵢ*Δ₁/R₁, Cᵢ denoting a selected fraction with an index i of available fractions for the first edge interpolator 711 based on the phase modulation code, and R denoting the resolution of the first edge interpolator 711. The second edge interpolator 712 may output a second edge interpolated signal that may include an edge with a time delay (e.g. relative to the first input signal) of Cⱼ*Δ₁/R₁, Cⱼ denoting a fraction that is different from the selected fraction for the first edge interpolator 711 based on the phase modulation code.

In order to provide output signals with the minimum phase difference achievable with the first stage 710, the fraction Cᵢ and the fraction Cⱼ may be subsequent fractions achievable by two substantially equally structured edge interpolators. In this illustrative example, assuming that for 8 possible fractions Cᵢ, and 0≤i<8; C₀ causing the time difference between the first input signal and an output signal to be 0, and C₇ causing the time difference between the first input signal and an output signal to be maximum, j may be selected such that j=i+1 or j=i−1.

The second stage 720 may output edge interpolated signals 726 having a second phase difference that is a fraction of the phase difference of the edge interpolated signals 716 received from the first stage 710. Illustratively, the first edge interpolator 721 may receive the first and the second edge interpolated signals 716 from the first stage 710 and perform an edge interpolation to the first and the second edge interpolated signals 716 based on a phase modulation code. In this illustration, the first edge interpolator 721 includes 16 unit cells and in a unary configuration, the 16 unit cells may provide 16 resolution steps, providing a configurable interpolation of an edge of an output signal of the second edge interpolator 721 in accordance with D*Δ₂/16, Δ₂ being the time difference between the first and the second edge interpolated signals 716 and D being a selectable integer based on a portion of the phase modulation code associated with the second stage 720. In other words, the first edge interpolator 721 may provide a plurality of time delays (e.g. relative to the first or the second edge interpolated signals 716), and each time delay may correspond to a fraction of the time difference between the first and the second edge interpolated signals 716 selected from of a plurality of fractions achievable based on the number of unit cells included in the first edge interpolator 721. In any event, Δ₂ being the time difference between the first and the second edge interpolated signals 716, the output signal of the first edge interpolator 721 has a time difference, illustratively with the first edge interpolated signal, of a fraction of the time difference between the first and the second edge interpolated signals 716 Δ₂, the fraction being between 0 and 1.

The second edge interpolator 722 may also receive the first and the second edge interpolated signals 716 and perform an edge interpolation to the first and the second edge interpolated signals 716 based on a phase modulation code. In this illustration, the second edge interpolator 721 also includes 16 unit cells and in a unary configuration, the 16 unit cells may provide 16 resolution steps, providing a configurable interpolation of an edge of an output signal of the second edge interpolator 722 in accordance with D*Δ₂/16, Δ₂ being the time difference between the first and the second edge interpolated signals 716 and D being a selectable integer based on a portion of the phase modulation code associated with the second stage 720. In other words, the second edge interpolator 722 may provide a plurality of time delays (e.g. relative to the first or the second edge interpolated signal), and each time delay may correspond to a fraction of the time difference between the first and the second edge interpolated signals 716 selected from a plurality of fractions achievable based on the number of unit cells included in the second edge interpolator 722. In any event, Δ₂ being the time difference between the first and the second edge interpolated signals 716, the output signal of the second edge interpolator 721 has a time difference illustratively relative to the first edge interpolated signal of the first stage 710 of a fraction of the time difference between the first and the second edge interpolated signals 716 Δ₂, the fraction being between 0 and 1.

In order to obtain, at the output of the second stage 720, edge interpolated signals having a second phase difference Δ₃ that is a fraction of the time difference between the first and the second edge interpolated signals 716 Δ₂, the first edge interpolator 721 and the second edge interpolator 722 may obtain two edge interpolated signals of which their respective edges are provided in different locations in the time domain. Illustratively, the first edge interpolator 721 may output a first edge interpolated signal of the second stage 720 that may include an edge with a time delay (e.g. relative to the first edge interpolated signal of the first stage 710) of Dᵢ*Δ₂/R₂, Dᵢ denoting a selected fraction with an index i of available fractions for the second edge interpolator 721 based on the phase modulation code, and R₂ denoting the resolution of the second edge interpolator 722. The second edge interpolator 722 may output a second edge interpolated signal of the second stage 720 that may include an edge with a time delay (e.g. relative to the first edge interpolated signal of the first stage 710) of Dⱼ*Δ₂/R₂, Dⱼ denoting a fraction that is different from the selected fraction for the first edge interpolator 721 of the second stage 720 based on the phase modulation code.

In order to provide output signals with the minimum phase difference achievable with the second stage 720, the fraction Dᵢ and the fraction Dⱼ may be subsequent fractions achievable by two substantially equally structured edge interpolators. In this illustrative example, assuming that for 16 possible fractions Dᵢ, and 0≤i<16; D₀ causing the time difference between the first edge interpolated signal of the first stage 710 and an output signal to be 0, and D₁₆ causing the time difference between the first edge interpolated signal of the first stage 710 and an output signal to be maximum, j may be selected such that j=i+1 or j=i−1.

The third stage 730 may output at least one edge interpolated signal, having a third phase difference that is a fraction of the phase difference of the edge interpolated signals 726 received from the second stage 720. Illustratively, the first edge interpolator 731 may receive the first and the second edge interpolated signals 726 from the second stage 720 and perform an edge interpolation to the first and the second edge interpolated signals 726 based on a phase modulation code. In this illustration, the first edge interpolator 731 includes 32 unit cells and in a unary configuration, the 32 unit cells may provide 32 resolution steps, providing a configurable interpolation of an edge of an output signal of the first edge interpolator 731 in accordance with E*Δ₃/32, Δ₃ being the time difference between the first and the second edge interpolated signals 726 and D being a selectable integer based on a portion of the phase modulation code associated with the third stage 730. In other words, the first edge interpolator 731 may provide a plurality of time delays (e.g. relative to the first or the second edge interpolated signals 726), and each time delay may correspond to a fraction of the time difference between the first and the second edge interpolated signals 726 selected from of a plurality of fractions achievable based on the number of unit cells included in the first edge interpolator 731. In any event, Δ₃ being the time difference between the first and the second edge interpolated signals 726, the output signal of the first edge interpolator 731 has a time difference, illustratively with the first edge interpolated signal at the output of the second stage 720, of a fraction of the time difference between the first and the second edge interpolated signals 726 Δ₃, the fraction being between 0 and 1.

The second edge interpolator 732 may also receive the first and the second edge interpolated signals 726 and perform an edge interpolation to the first and the second edge interpolated signals 726 based on a phase modulation code. In this illustration, the second edge interpolator 731 also includes 32 unit cells and in a unary configuration, the 32 unit cells may provide 32 resolution steps, providing a configurable interpolation of an edge of an output signal of the second edge interpolator 732 in accordance with E*Δ₃/16, Δ₃ being the time difference between the first and the second edge interpolated signals 726 and E being a selectable integer based on a portion of the phase modulation code associated with the second stage 730. In other words, the second edge interpolator 732 may provide a plurality of time delays (e.g. relative to the first or the second edge interpolated signal at the output of the second stage 720), and each time delay may correspond to a fraction of the time difference between the first and the second edge interpolated signals 726 selected from a plurality of fractions achievable based on the number of unit cells included in the second edge interpolator 732. In any event, Δ₃ being the time difference between the first and the second edge interpolated signals 726, the output signal of the second edge interpolator 731 has a time difference illustratively relative to the first edge interpolated signal of the second stage 720 of a fraction of the time difference between the first and the second edge interpolated signals 726 Δ₂, the fraction being between 0 and 1.

In order to obtain, at the output of the third stage 730, edge interpolated signals having a third phase difference Δ₄ that is a fraction of the time difference between the first and the second edge interpolated signals 726 Δ₃, the first edge interpolator 731 and the second edge interpolator 732 may obtain two edge interpolated signals of which their respective edges are provided in different locations in the time domain. Illustratively, the first edge interpolator 731 may output a first edge interpolated signal of the third stage 730 that may include an edge with a time delay (e.g. relative to the first edge interpolated signal of the second stage 720) of Eᵢ*Δ₃/R₃, Eᵢ denoting a selected fraction with an index i of available fractions for the second edge interpolator 731 based on the phase modulation code, and R₃ denoting the resolution of the second edge interpolator 732. The second edge interpolator 732 may output a second edge interpolated signal of the third stage 730 that may include an edge with a time delay (e.g. relative to the first edge interpolated signal of the second stage 720) of Eⱼ*Δ₃/R₃, Eⱼ denoting a fraction that is different from the selected fraction for the first edge interpolator 731 of the third stage 730 based on the phase modulation code.

In order to provide output signals with the minimum phase difference achievable with the third stage 730, the fraction Eᵢ and the fraction Eⱼ may be subsequent fractions achievable by two substantially equally structured edge interpolators. In this illustrative example, assuming that for 32 possible fractions Eᵢ, and 0≤i<32; E₀ causing the time difference between the first edge interpolated signal of the second stage 720 and an output signal to be 0, and E₁₆ causing the time difference between the first edge interpolated signal of the second stage 720 and an output signal to be maximum, j may be selected such that j=i+1 or j=i−1.

It is to be noted that, in case the third stage 730 is the last stage of the plurality of stages of the apparatus configured to provide a phase modulated output signal, in some examples, the third stage 730 (or the last stage in general) may include only a single edge interpolator (e.g. the first edge interpolator 731). The phase of the output of the first edge interpolator 731 may be defined relative to the first or the edge interpolated signal of the second stage 720. In some examples, the third stage may include the first edge interpolator and the second edge interpolator, such that one of the first 731 and the second edge interpolators 732 may have a reversed polarity compared to the other for a better linearity and impedance matching through the transmission circuitry. In accordance with various aspects, one or more stages of the plurality of stages may include dummy unit cells (i.e. unit cell structures which are not configured to apply edge interpolations) to match the exact loading

It is to be noted that, although aspects described in this disclosure generally exemplify three stages, an apparatus may include any N number of stages, N being an integer greater or equal to 2. As the number of stages increases, the complexity may also grow but further phase-resolutions can be obtainable for longer phase modulation codes. In certain examples, noting that the stages are provided in a cascade configuration, the apparatus may include one or more buffers between at least two subsequent stages, or between each two subsequent stages.

Referring to a first stage as the stage receiving input signals with the greatest time difference among all stages, and to a last stage as the stage receiving input signals with the smallest time difference among all stages, edge interpolators of the first stage may include the greatest number of interpolators among all stages and edge interpolators of the last stage may include the smallest number of interpolators among all stages. In some examples, the number of interpolators of each edge interpolator may decrease with each subsequent stage between the first stage and the last stage in the direction towards the last stage. In some examples as depicted in FIG. 7, edge interpolators of the first stage may include the smallest number of interpolators among all stages and edge interpolators of the last stage may include the greatest number of interpolators among all stages. In some examples, the number of interpolators of each edge interpolator may increase with each subsequent stage between the first stage and the last stage in the direction towards the last stage. In some examples, the number of interpolators of each stage may be designated based on desired phase and/or phase modulation code relationships without any ordering for neighboring stages.

It is to be noted herein that various aspects described herein may have a particular importance for mmWave applications, in which a fine interpolation may be desired for multiple phases (e.g. 20-phases) instead of a single phase, which may result in a 5-fold multiplication, and in which a higher resolution may be desirable before multiplication. For instance, assuming that a 70 GHz output frequency is desired for 0, 45, 90, 135, 180, 225, 270, 315, and 380 degrees with a tunability of 0.35 degree resolution, the desired resolution at 14 GHz may be 0.07 deg. Hence, each of the multiple phases (e.g. 20-phases) may require a DCEI array consisting of 9/0.1=128 DCEI unit cells in various conventional methods. For illustratively 20 phases, the total number of DCEI unit cells may be 128×20=2560 accounting just the final stage using conventional method. For this reason, conventional methods may require very large buffers for each of the multiple phases, which may consume around 70 mA, just for the buffers. Whereas illustratively, a 1b×2b×4b implementation in which the phase modulation code is divided into segments of 1 bit, 2 bit, and 4 bit, for multiple stages approach described herein, would reduce the total number of inverters to 20×26=520 which in return may reduce the total power consumption by 4 times and may not need any buffer at all; hence the overall power reduction may be considered in the orders of magnitude.

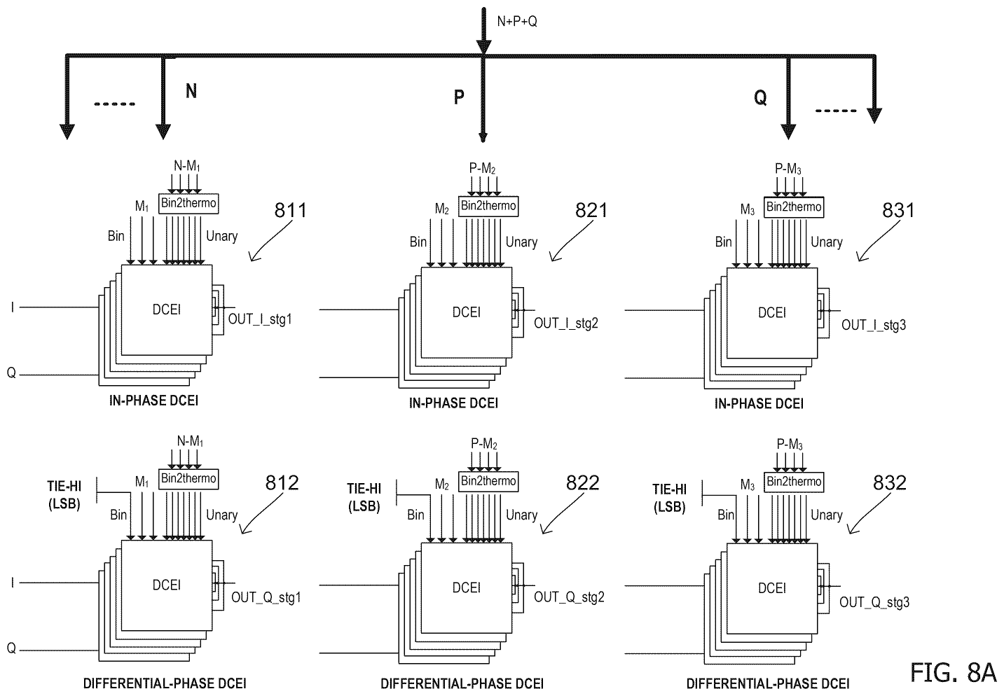

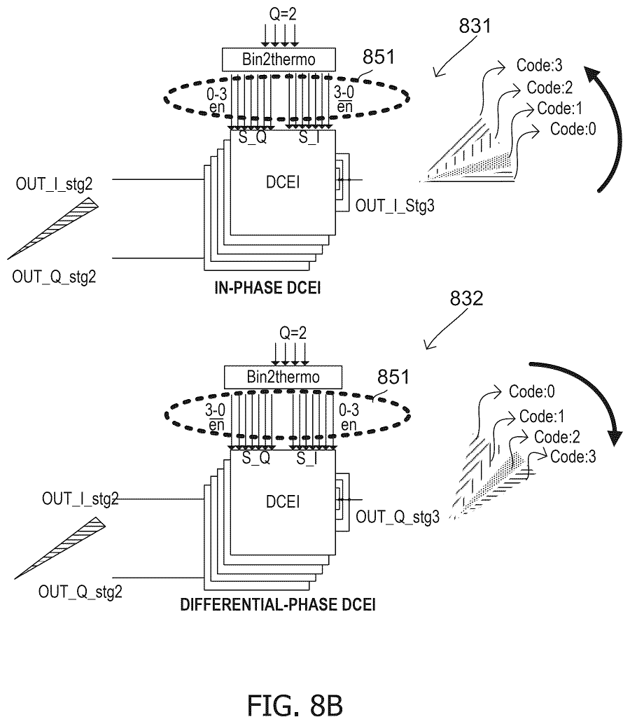

FIG. 8A shows an exemplary schematic illustration of an apparatus in accordance with various aspects of this disclosure. Complimenting to aspects described with respect to FIG. 7, the apparatus may include a plurality of stages, illustratively a first stage, a second stage, and a third stage, each stage including a first edge interpolator 811, 821, 831, and a second edge interpolator 812, 822, 832, which are illustrated herein as an in-phase DCEI and a differential-phase DCEI complimenting the corresponding functions of the respective edge interpolators within the apparatus, such that one (e.g. the first) edge interpolator provides an in-phase signal for a subsequent stage and another one (e.g. the second) edge interpolator provides a differential signal for the subsequent stage to obtain relative time difference (i.e. phase difference).

In this illustrative example, the first stage includes first edge interpolator 811 and second edge interpolator 812. The second stage includes first edge interpolator 821 and second edge interpolator 822. The third stage includes first edge interpolator 831 and second edge interpolator. Illustratively, the first stage may be the input stage to the apparatus, which may receive a first input signal (e.g. an in-phase signal, denoted as I) and a second input signal (e.g. a quadrature phase signal, denoted as Q). Illustratively, an oscillator may provide the IQ signals. In some examples, a previous phase generator may provide the IQ signals. In some examples, the previous phase generator may include a similar apparatus including edge interpolators. Although, the apparatus has depicted to include three stages, it may include further stages as depicted herein, to which corresponding portion of a phase modulation code to be provided.

In some aspects, each edge interpolator may determine an amount of edge interpolation to be applied, or in other words determine a location at the time domain between two (rising or falling) edges of input signals to the respective edge interpolator, at which an edge of the respective edge interpolated signal is to be located, based on a respective portion of a phase modulation code that a processor (e.g. digital modem, the processor 310, the DFE 420) may provide. As previously mentioned, each edge interpolator may include a binary controlled edge interpolator array and/or a unary controlled edge interpolator array. In the mixed approach, the binary controlled array including multiple interpolators may operate with a first portion of received portion of the phase modulation code and the unary controlled array including multiple interpolators may operate with a second portion of the received portion of the phase modulation code.

In this example, a processor may provide a phase modulation code including PM=[. . . N;P;Q . . . ]. A first segment (i.e. portion) N of the phase modulation code may be configured to control the first stage. A second segment P of the phase modulation code may be configured to control the second stage. A third segment Q of the phase modulation code may be configured to control the third stage. In this illustrative example, the processor provides each respective segment to respective edge controllers of the respective stage. In some examples, the processor may also provide their respective segments of the phase modulation code to respective further stages.

As each edge interpolator illustrated herein includes both a binary controlled array and a unary controlled array, noting that the phase modulation code may include a binary code, the binary controlled array of each edge interpolator may receive only a first portion of the respective segment of the phase modulation code associated with the respective stage. The unary controlled array of each edge interpolator may be coupled to a binary to unary (depicted as Bin2thermo) converter that converts a second portion of the respective segment of the phase modulation code associated with the respective stage and provides the converted code into the unary controlled array of the respective edge interpolator.

Illustratively, the first segment N may be associated with the first stage. First edge interpolator 811 may receive a first portion of the N, denoted as M₁ in binary code, and a second portion of the N, denoted as N-M₁ may input to a first binary to unary converter and first edge interpolator 811 accordingly receives unary representation of N-M₁. The second segment P may be associated with the second stage. First edge interpolator 821 may receive a first portion of the P, denoted as M₂ in binary code, and a second portion of the P, denoted as P-M₂ may input to a second binary to unary converter and first edge interpolator 821 accordingly receives a unary representation of P-M₂. Similarly, first edge interpolator 831 may receive a first portion of the Q, denoted as M₃ in binary code, and a second portion of the Q, denoted as Q-M₃ may input to a third binary to unary converter and first edge interpolator 831 accordingly receives a unary representation of Q-M₃.

Accordingly, first edge interpolator 811 may receive input IQ signals having a phase difference Δ₁ in between. In other words, edges of the I signal and edges of the Q signal is separated by Δ₁ in time domain. First edge interpolator 811 may provide an edge interpolation based on the segment N. First edge interpolator 811 may accordingly output a first edge interpolated signal of which edges of the first edge interpolated signal would be separated by Δ₁ₐ in the time domain from, exemplarily, the edges of the I signal, which Δ₁ₐ is smaller than Δ₁. In other words, the first edge interpolated signal may be considered as a time shifted version of the I signal (or the Q signal), such that amount of the time shift is smaller than Δ₁ through the edge interpolation indicated by the segment N.

Similarly, first edge interpolator 821 may receive output signals of the first stage, namely the first edge interpolated signal of the first stage, which first edge interpolator 811 may output, and a second edge interpolated signal of the first stage, which second edge interpolator 812 may output. Output signals of the first stage may have a phase difference Δ₂ in between. In other words, edges of the first edge interpolated signal of the first stage and edges of the second edge interpolated signal of the first stage may be separated by Δ₂ in time domain, noting that Δ₂<Δ₁ as described in this disclosure (e.g. based on number of interpolators of first edge interpolator 811 and second edge interpolator 812). First edge interpolator 821 may provide an edge interpolation based on the segment P. First edge interpolator 821 may accordingly output a first edge interpolated signal of which edges of the first edge interpolated signal output by first edge interpolator 821 would be separated by Δ₂ₐ in the time domain from, exemplarily, the edges of the first edge interpolated signal of the first stage, which Δ₂ₐ is smaller than Δ₂. In other words, the first edge interpolated signal output by first edge interpolator 821 may be considered as a time shifted version of the first edge interpolated signal of the first stage (or the second edge interpolated signal of the first stage), such that amount of the time shift is smaller than Δ₂ through the edge interpolation indicated by the segment P.

Moreover, first edge interpolator 831 may receive output signals of the second stage, namely the first edge interpolated signal of the second stage, which first edge interpolator 821 may output, and a second edge interpolated signal of the second stage, which second edge interpolator 822 may output. Output signals of the second stage may have a phase difference Δ₃ in between. In other words, edges of the first edge interpolated signal of the second stage and edges of the second edge interpolated signal of the second stage may be separated by Δ₃ in time domain, noting that Δ₃<Δ₂ as described in this disclosure (e.g. based on number of interpolators of first edge interpolator 821 and second edge interpolator 822). First edge interpolator 831 may provide an edge interpolation based on the segment Q. First edge interpolator 831 may accordingly output a first edge interpolated signal of which edges of the first edge interpolated signal output by first edge interpolator 831 would be separated by Δ₃ₐ in the time domain from, exemplarily the edges of the first edge interpolated signal of the second stage, which Δ₃ₐ is smaller than Δ₃. In other words, the first edge interpolated signal output by first edge interpolator 831 may be considered as a time shifted version of the first edge interpolated signal of the second stage (or the second edge interpolated signal of the second stage), such that amount of the time shift is smaller than Δ₃ through the edge interpolation indicated by the segment P.

The apparatus may include multiple stages provided in a cascade configuration, such that each stage provides its output including edge interpolated signals to an input of a subsequent stage. Each stage may provide a respective output including respective edge interpolated signals based on time difference/time delay/phase difference between its input signals. As the apparatus may provide a phase modulated output signal at the output of the last stage, which the phase of the phase modulated output signal is indicated by the phase modulation code, segments assigned to each stage may be ordered in accordance with the order of the stages within the apparatus. Illustratively, recognizing that the phase modulation code may include bits ordered from MSB to LSB, the first stage may receive the first segment N, and N may include bits including the MSB. Similarly, the third stage may receive the third segment Q, and Q may include bits including the LSB.

In accordance with various aspects provided herein, second edge interpolators 812, 822, 832 may also determine an amount of edge interpolation to be applied, or in other words determine a location at the time domain between two (rising or falling) edges of input signals to the respective edge interpolator, at which an edge of the respective edge interpolated signal is to be located, based on a respective portion of a phase modulation code provided to respective first edge interpolators 811, 821, 831 of the respective stage. As second edge interpolators operate in a fashion to generate respective second edge interpolated signals complimenting to first edge interpolated signals generated by respective first edge interpolators of the respective stage in order to generate a phase difference for the input of the next stage, second edge interpolators may perform edge interpolation based on an adjusted version of the respective portion of the phase modulation code, noting that the generated phase difference is smaller than the phase difference of the input signals received by the respective stage.

In other words, each second edge interpolator 812, 822, 832 may be configured to output a second edge interpolated signal, such that the phase of the first edge interpolated signal is rotatable at each stage, and the phase difference between the first edge interpolated signal and the second edge interpolated signal of each stage is fixed. In other words, each first edge interpolator 811, 821, 831 and respective second edge interpolator 812, 822, 832 of each stage may be configurable to provide a plurality of time delays between the first edge interpolated signal and the second interpolated signal based on the portion of the phase modulation code associated with the respective stage. Particularly, each delay of the plurality of time delays may correspond to a fraction of the phase difference of the input signals of the respective stage, selected from a plurality of fractions based on the portion of the phase modulation code associated with the respective stage.

In particular, considering that each first edge interpolator 811, 821, 831 of a stage may be structurally equivalent to a respective second edge interpolator 812, 822, 832 of the respective stage, and each edge interpolator (i.e. first edge interpolator and second edge interpolator) of a stage may be configured to provide an output edge interpolated signal as a time-shifted representation of one of the received input signals (e.g. first input signal or first edge interpolated signal of the previous stage), assuming that each edge interpolator may provide S number of predefined time delays (e.g. for first edge interpolator 811, (Δ_{1a,1}, Δ_{1a,2}, Δ_{1a,3}, . . . , Δ_{1a,s}), where S may differ for each stage, the amount of time delay to be applied by respective first edge interpolator 811, 821, 831 of each stage and the amount of time delay to be applied by respective second edge interpolator 812, 822, 832 of that stage may be neighboring time delays.

To provide that, respective second edge interpolator 812, 822, 832 of each stage may receive a bit shifted version of the same portion of the phase modulation code provided to respective first edge interpolator 811, 821, 831 associated with the respective stage. Illustratively, respective second edge interpolator 812, 822, 832 of each stage may perform an edge interpolation based on a received phase modulation code, such that the LSB of the respective portion of the phase modulation code, which was provided to respective first edge interpolator 811, 821, 831, may be tied to a high signal or a low signal depending on the application.

Illustratively, while first edge interpolator 811 receives the first segment N as in a first portion of the N, denoted as M1 in binary code, and as in a second portion of the N corresponding to a unary representation of N-M1, respective second edge interpolator 812 may receive the first segment N as in a first portion of the N, denoted as M1 in binary code of which the LSB is tied to a high signal as illustrated herein, and as in a second portion of the N corresponding to a unary representation of N-M1. Similarly, while first edge interpolator 821 receives the second segment P as in a first portion of the P, denoted as M2 in binary code, and as in a second portion of the P corresponding to a unary representation of P-M2, respective second edge interpolator 822 may receive the second segment P as in a first portion of the P, denoted as M2 in binary code of which the LSB is tied to a high signal as illustrated herein, and as in a second portion of the P corresponding to a unary representation of P-M2. Moreover, while first edge interpolator 831 receives the third segment Q as in a first portion of the Q, denoted as M3 in binary code, and as in a second portion of the Q corresponding to a unary representation of Q-M3, respective second edge interpolator 832 may receive the third segment Q as in a first portion of the Q, denoted as M3 in binary code of which the LSB is tied to a high signal as illustrated herein, and as in a second portion of the Q corresponding to a unary representation of P-M3. It is to be noted that LSB of the respective unary representations may also be tied to a low signal.

To summarize, through use of multiple stages connected in a cascade configuration, where each stage has an in-phase path and a differential-phase path, in accordance with various aspects described herein, the output phase on both of these paths rotates based on the phase modulation code associated with the respective stage but the phase difference between the output signals is kept constant by bit shifting the LSB of the differential path. Accordingly, the total phase rotation created by each subsequent stage may be equal to one phasor rotation of a previous stage. In some examples, a subsequent stage can be compared to a binary sized DCEI (functionality-wise) for the previous stage even though it can consist of both bin/unary or combination of both.

An illustration including numerical examples may be provided herein in accordance with the illustration depicted in FIG. 8A. Assuming that the phase modulation code includes 9 bits to generate a phase modulated output signal by the apparatus including the first stage, the second stage, and the third stage. The input signal to the apparatus (i.e. to the first stage) may include IQ signals having a 22.5 degree phase difference.

A first portion of the phase modulation code including 4 bits (including the MSB of the phase modulation code) may be associated with the first stage including first edge interpolator 811 and second edge interpolator 812, each including a thermometric interpolator array of 16 unit cells. A second portion of the phase modulation code including 3 bits following the first portion of the phase modulation code may be associated with the second stage including first edge interpolator 821 and second edge interpolator 822, each including a thermometric interpolator array of 9 unit cells. A third portion of the phase modulation code including 2 bits following the second portion of the phase modulation code may be associated with the third stage including first edge interpolator 831 and second edge interpolator, each including a thermometric interpolator array of unit cells.

In this configuration, first edge interpolator 811 may receive, as inputs, the IQ signals and output a first edge interpolated signal of the first stage. The first edge interpolated signal may include a time-shifted version of the I signal (or the Q signal) shifted with a time delay of 16 available time delays, which the time delay is based on the first portion of the phase modulation code. Illustratively, the phase of the first edge interpolated signal relative to the I signal may be P₀+C*Δ₁/16, Δ₁ being the phase difference between IQ signals i.e. 22.5 degrees, P₀ being the phase of the I signal (i.e. 0 for in-phase signal) and C being an integer between 1 and 16 based on the first portion of the phase modulation code. Illustrating C with 8, the phase of the first edge interpolated signal may be 11.25 degrees.

Second edge interpolator 812 may output a second edge interpolated signal of the first stage. The second edge interpolated signal may include a time-shifted version of the I signal (or the Q signal) shifted with a time delay of 16 available time delays, which the time delay is based on the first portion of the phase modulation code and/or the time delay configured for first edge interpolator 811 of the first stage to provide a phase difference. As described herein, the time delay that second edge interpolator 812 applies may be a neighboring time delay of available time delays, which the neighboring time delay is subsequent to the time delay configured for first edge interpolator 811. Illustratively, the phase of the second edge interpolated signal relative to the I signal may be P₀+(C+1)*Δ₁/16 or P₀+(C−1)*Δ₁/16, Δ₁ being the phase difference between IQ signals i.e. 22.5 degrees, and C being the integer between 1 and 16 based on the first portion of the phase modulation code selected for first edge interpolator 811 of the first stage.

Illustrating C with 8, the phase of the second edge interpolated signal of the first stage may be 12.65625 degrees (or 9.84375 degrees). This would cause the output of the first stage including the first edge interpolated signal and the second edge interpolated signal, such that a phase slice within the input phase difference of 22.5 degrees is provided to the next stage, which includes a phase difference of 1.40625 degrees that is fixed, and the phase (e.g. associated with the first edge interpolated signal of the first stage) may be rotatable between the phase of the I signal and the phase of the Q signal based on the first portion of the phase modulation code.

In this configuration, first edge interpolator 821 may receive, as inputs, the first edge interpolated signal and the second edge interpolated signal of the first stage and output a first edge interpolated signal of the second stage. The first edge interpolated signal of the second stage may include a time-shifted version of the first edge interpolated signal of the first stage shifted with a time delay of 9 available time delays, which the time delay is based on the second portion of the phase modulation code. Illustratively, the phase of the first edge interpolated signal of the second stage relative to the first edge interpolated signal of the first stage may be P₁+D*Δ₂/9, Δ₂ being the phase difference between the first edge interpolated signal of the first stage and the second edge interpolated signal of the first stage i.e. 1.40625 degrees, P₁ being the phase of the first edge interpolated signal of the first stage relative to the I signal being at 11.25 degrees, and D being an integer between 1 and 9 based on the second portion of the phase modulation code. Illustrating D with 4, the phase of the first edge interpolated signal of the second stage may be 11.25+0.625=11.875 degrees.

Second edge interpolator 822 may receive, as inputs, the first edge interpolated signal and the second edge interpolated signal of the first stage and output a second edge interpolated signal of the second stage. The second edge interpolated signal of the second stage may include a time-shifted version of the first edge interpolated signal of the first stage shifted with a time delay of 9 available time delays, which the time delay is based on the second portion of the phase modulation code and/or the time delay configured for first edge interpolator 821 of the second stage to provide a phase difference. As described herein, the time delay that second edge interpolator 822 applies may be a neighboring time delay of available time delays, which the neighboring time delay is subsequent to the time delay configured for first edge interpolator 821. Illustratively, the phase of the second edge interpolated signal of the first stage relative to the I signal may be P₁+(D+1)*Δ₂/9 or P₁+(d−1)*Δ₂/9, Δ₂ being the phase difference between the first edge interpolated signal of the first stage and the second edge interpolated signal of the first stage i.e. 1.40625 degrees, P₁ being the phase of the first edge interpolated signal being at 11.25 degrees relative to the I signal, and D being the integer between 1 and 9 based on the second portion of the phase modulation code selected for first edge interpolator 821 of the second stage.

Illustrating D with 4, the phase of the second edge interpolated signal of the second stage may be 12.03125 degrees (or 11.71875 degrees). This would cause the output of the second stage including the first edge interpolated signal and the second edge interpolated signal, such that a phase slice within the input phase difference of 0.15625 degrees starting from 11.875 degrees is provided to the next stage, which includes a phase difference of 0.15625 degrees that is fixed, and the phase (e.g. associated with the first edge interpolated signal of the first stage) may be rotatable between the phase of the first edge interpolated signal of the first stage and the second edge interpolated signal of the first stage based on the first portion of the phase modulation code.

In this configuration, first edge interpolator 831 may receive, as inputs, the first edge interpolated signal and the second edge interpolated signal of the second stage and output a first edge interpolated signal of the third stage. The first edge interpolated signal of the third stage may include a time-shifted version of the first edge interpolated signal of the second stage shifted with a time delay of 4 available time delays, which the time delay is based on the third portion of the phase modulation code. Illustratively, the phase of the first edge interpolated signal of the third stage relative to the first edge interpolated signal of the second stage may be P₃+E*Δ₃/4, Δ₃ being the phase difference between the first edge interpolated signal of the second stage and the second edge interpolated signal of the second stage i.e. 0.15625 degrees, P₃ being the phase of the first edge interpolated signal of the second stage being at 11.875 degrees relative to the I signal, and E being an integer between 1 and 4 based on the third portion of the phase modulation code. Illustrating E with 2, the phase of the first edge interpolated signal of the second stage may be 11.875+0.078125=11.953125 degrees. Illustratively, the first edge interpolator 831 may output the first edge interpolated signal having the phase 11.953125 degrees relative to the I signal as the phase modulated output signal.

Moreover, to illustrate further operation including more than three stages, second edge interpolator 832 may receive, as inputs, the first edge interpolated signal and the second edge interpolated signal of the second stage and output a second edge interpolated signal of the third stage. The second edge interpolated signal of the third stage may include a time-shifted version of the first edge interpolated signal of the second stage shifted with a time delay of 4 available time delays, which the time delay is based on the third portion of the phase modulation code and/or the time delay configured for first edge interpolator 831 of the third stage, illustratively to provide a phase difference for a subsequent stage. As described herein, the time delay that second edge interpolator 832 applies may be a neighboring time delay of available time delays, which the neighboring time delay is subsequent to the time delay configured for first edge interpolator 831. Illustratively, the phase of the second edge interpolated signal relative to the I signal may be ₃+(E+1)*Δ₃/4 or P₃+(E−1)*Δ₃/4, Δ₃ being the phase difference between the first edge interpolated signal of the second stage and the second edge interpolated signal of the second stage i.e. 0.15625 degrees, P₃ being the phase of the first edge interpolated signal of the second stage being at 11.875 degrees relative to the I signal, and E being the integer between 1 and 4 based on the third portion of the phase modulation code selected for first edge interpolator 831 of the third stage.

Illustrating E with 2, the phase of the second edge interpolated signal of the third stage may be 11.9921875 degrees (or 11.7578125 degrees). This would cause the output of the second stage including the first edge interpolated signal and the second edge interpolated signal, such that a phase slice within the input phase difference of 0.0390625 degrees starting from 11.953125 degrees is provided to the subsequent stage, which includes a phase difference of 0.0390625 degrees that is fixed, and the phase may be rotatable between the first edge interpolated signal of the second stage and the second edge interpolated signal of the second stage based on the first portion of the phase modulation code.

It is to be noted herein that, the first stage of the apparatus that has been described herein may be deemed as quite small compared to conventional methods of implementing a 9-bit conventional DCEI without involving cascade multiple stages. Through implementation of such small stages to obtain relatively a finer resolution, buffer stages between DCEIs may become irrelevant and not needed, or buffer sizes may be reduced. Accordingly, in mm Wave DTX architectures, the apparatus may obtain a significant power conservation improvement compared to conventional methods.

FIG. 8B shows an exemplary schematic illustration of a last stage of an apparatus in accordance with various aspects of this disclosure. Illustratively, the last stage of the apparatus may be the third stage including the first and second edge interpolators 831, 832. In this illustrative example, the last stage includes two edge interpolators to which the corresponding segment of the phase modulation code Q has been provided. As illustratively other edge interpolators described herein, the binary to thermo converter may convert the code Q into a unary code, which is then used to configure which interpolators of the respective edge interpolator operate via first input selectors and second input selectors.

Illustratively, the unary code may be provided for the first input selectors and a reverse order of the unary code may be provided for the second input selectors. As can be seen from 851, in an example, the first binary to thermo converter of the first edge interpolator 831 is coupled to provide a first unary code for the first input selectors and is coupled to provide a second unary code that is a reverse order of the first unary code to the second input selectors. On the other hand, the second edge interpolator 832 may receive the second unary code for the first input selectors and may receive the first unary code for the second input selectors. In other words, the polarity between the first input selectors and the second input selectors of the second edge interpolator 832 is reversed compared to the first input selectors and the second input selectors of the first edge interpolator 831 to ensure a load matching and linearity.

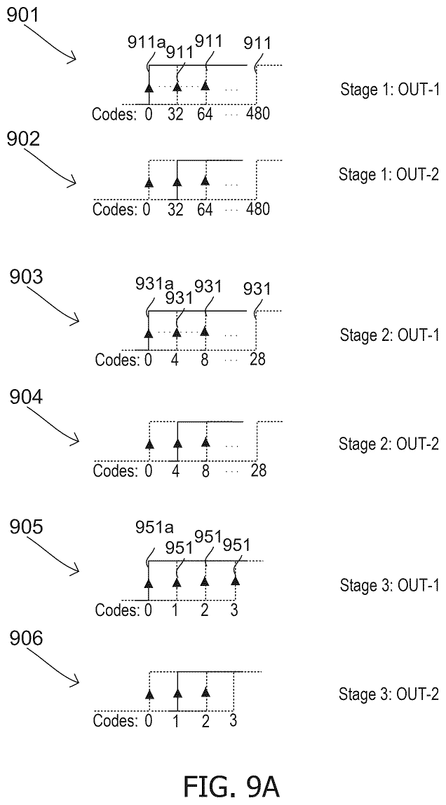

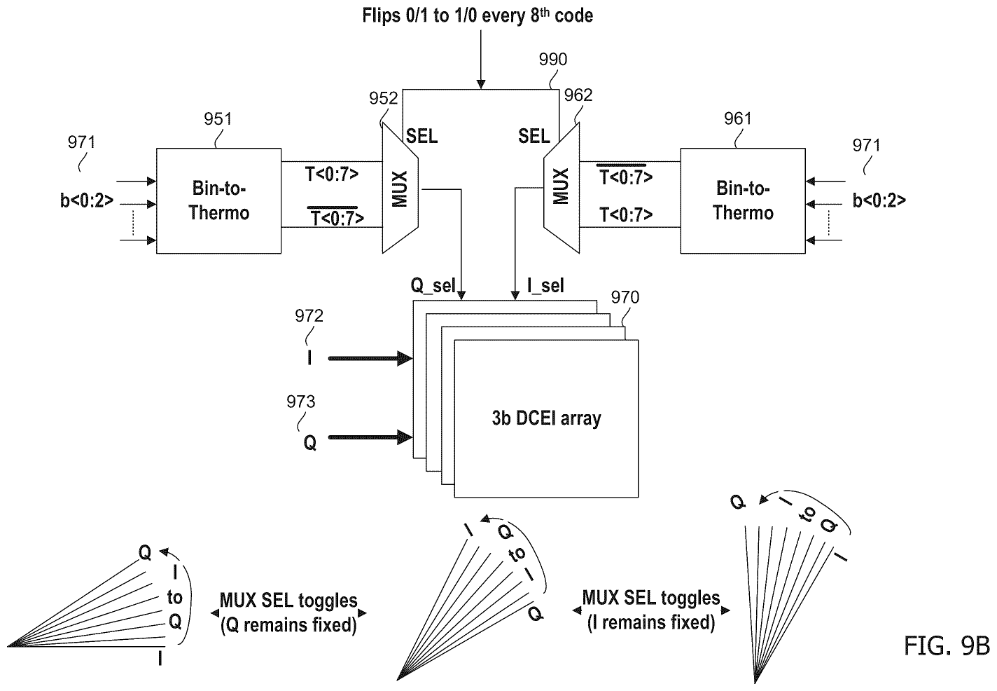

FIG. 9A shows an exemplary illustration of edges of signals associated with an apparatus including three edge interpolator stages described exemplarily in accordance with FIG. 8A. Illustrating the example of a phase modulation code of 9 bits, aspects associated with the phase modulation code have been illustrated in decimals for brevity, between 0 and 511. Also, for an easier representation, first edge interpolator 811 of the first stage is depicted to be configured such that first edge interpolated signal at the output of first edge interpolator 811 is the I signal without any time delay.

The first graph 901 illustrates possible configurations 911a, 911 of edges of the first edge interpolated signal of the first stage responsive to the first segment of the phase modulation code associated with the first stage. The graph illustrates possible edges 911a, 911 of the first edge interpolated signal. Code 0 may correspond to the first edge interpolated signal having an edge without any time difference to an edge of the I signal. In other words, 911a configuration illustrates the phase configuration of the first edge interpolated signal of the first stage.

With the first segment being a 4-bit code, in a unary configuration, the first edge interpolated signal may have 16 different phases (relative to the I signal), a first phase corresponding to code 0, a second phase corresponding to code 32, a third phase corresponding to 64 . . . , and a sixteenth phase corresponding to code 480. The location of the edges corresponding to some of these phases in the time domain have been illustrated in 901. As indicated, illustratively, the first segment may cause the first edge interpolated signal to have the same phase with the I signal, which is illustrated as 911a.

The second graph 902 illustrates possible configurations of edges of the second edge interpolated signal of the first stage responsive to the first segment of the phase modulation code associated with the first stage, in a manner that a neighboring phase configuration to the phase configuration of the first edge interpolated signal of the first stage 911a may apply. The graph illustrates possible edges of the second edge interpolated signal, similar to the first graph 901. With the first segment being a 4-bit code, in a unary configuration, the second edge interpolated signal may also have 16 different phases (relative to the I signal), a first phase corresponding to code 0, a second phase corresponding to code 32, a third phase corresponding to 64 . . . , and a sixteenth phase corresponding to code 480. The location of the edges corresponding to some of these phases in the time domain have been illustrated in 902. As indicated, illustratively, noting that the first segment may cause the first edge interpolated signal to have the same phase with the I signal, the edge of the second edge interpolated signal may be illustratively the edge illustrated for code 32.

Accordingly, the first stage may output the first edge interpolated signal of the first stage and the second edge interpolated signal of the first stage. An edge of the first edge interpolated signal of the first stage may be located at a designated location of available locations relative to the I signal in the time domain. An edge of the second edge interpolated signal of the first stage may be located at a neighboring available location of the designated location for the first edge interpolated signal from available locations in the time domain.

In this illustrative example, the first edge interpolated signal of the first stage and the second edge interpolated signal of the first stage defines a phase slice (or a time difference slice) between codes 0 and 32. Angular resolution of the first stage may be formulated as the following, θᵢ denoting the phase of the I signal and θⱼ denoting the phase of the Q signal input to the first stage, Φ_{stg1}=|θᵢ−θⱼ|/2⁴=Δθ/2⁴.

The third graph 903 illustrates possible configurations 931a, 931 of edges of the first edge interpolated signal of the second stage responsive to the second segment of the phase modulation code associated with the second stage. The graph illustrates possible edges 931a, 931 of the first edge interpolated signal. Code 0 may correspond to the first edge interpolated signal having an edge without any time difference to an edge of the I signal. In other words, 931a configuration illustrates the phase configuration of the first edge interpolated signal of the second stage.

With the second segment being a 3-bit code, in a unary configuration, the first edge interpolated signal of the second stage may have 8 different phases (relative to the I signal), a first phase corresponding to code 0, a second phase corresponding to code 4, a third phase corresponding to 8 . . . , and a sixteenth phase corresponding to code 28. The location of the edges corresponding to some of these phases in the time domain have been illustrated in 903. As indicated, illustratively, second first segment may cause the first edge interpolated signal of the second stage to have the same phase with the I signal, which is illustrated as 931a.

The fourth graph 904 illustrates possible configurations of edges of the second edge interpolated signal of the second stage responsive to the second segment of the phase modulation code associated with the second stage, in a manner that a neighboring phase configuration to the phase configuration of the first edge interpolated signal of the second stage 951a may apply. The graph illustrates possible edges of the second edge interpolated signal, similar to the third graph 903. With the second segment being a 3-bit code, in a unary configuration, the second edge interpolated signal may also have 8 different phases (relative to the I signal), a first phase corresponding to code 0, a second phase corresponding to code 4, a third phase corresponding to 8 . . . , and a sixteenth phase corresponding to code 28. The location of the edges corresponding to some of these phases in the time domain have been illustrated in 904. As indicated, illustratively, noting that the second segment may cause the first edge interpolated signal to have the same phase with the I signal, the edge of the second edge interpolated signal may be illustratively the edge illustrated for code 4.

Accordingly, the second stage may output the first edge interpolated signal of the second stage and the second edge interpolated signal of the second stage. An edge of the first edge interpolated signal of the second stage may be located at a designated location of available locations relative to the I signal in the time domain and/or the first edge interpolated signal of the first stage. An edge of the second edge interpolated signal of the second stage may be located at a neighboring available location of the designated location for the first edge interpolated signal of the second stage from available locations in the time domain.

In this illustrative example, the first edge interpolated signal of the second stage and the second edge interpolated signal of the second stage defines a phase slice (or a time difference slice) between codes 0 and 4. Angular resolution of second first stage may be formulated as the following, Φ_{stg2}=Φ_{stg1}/2³=Δθ/2⁷.

The fifth graph 905 illustrates possible configurations 951a, 951 of edges of the first edge interpolated signal of the third stage responsive to the third segment of the phase modulation code associated with the third stage. The graph illustrates possible edges 951a, 951 of the first edge interpolated signal. Code 0 may correspond to the first edge interpolated signal having an edge without any time difference to an edge of the I signal. In other words, 951a configuration illustrates the phase configuration of the first edge interpolated signal of the third stage.

With the second segment being a 2-bit code, in a unary configuration, the first edge interpolated signal of the second stage may have 4 different phases (relative to the I signal), a first phase corresponding to code 0, a second phase corresponding to code 1, a third phase corresponding to 2, and a fourth phase corresponding to code 3. The location of the edges corresponding to some of these phases in the time domain have been illustrated in 905. As indicated, illustratively, third first segment may cause the first edge interpolated signal of the third stage to have the same phase with the I signal, which is illustrated as 951a.

It is to be noted that as this was example was solely for the illustration, the first edge interpolated signal of the third stage may also be used to obtain a phase modulated signal output from the DTC. In this illustrative example, using the I signal input to first stage as an in-phase signal of the phase modulated signal output from the DTC, adding the first edge interpolated signal of the third stage to the I signal may result in a phase modulated signal output from the DTC having a phase difference of 0 degrees.

The sixth graph 906 illustrates possible configurations of edges of the second edge interpolated signal of the third stage responsive to the third segment of the phase modulation code associated with the third stage, in a manner that a neighboring phase configuration to the phase configuration of the first edge interpolated signal of the third stage 951a may apply. The graph illustrates possible edges of the second edge interpolated signal, similar to the fifth graph 905. With the second segment being a 2-bit code, in a unary configuration, the second edge interpolated signal may also have 4 different phases (relative to the I signal), a first phase corresponding to code 0, a second phase corresponding to code 1, a third phase corresponding to 2, and a fourth phase corresponding to code 3. The location of the edges corresponding to these phases in the time domain have been illustrated in 906. As indicated, illustratively, noting that the third segment may cause the first edge interpolated signal of the third stage to have the same phase with the I signal, the edge of the second edge interpolated signal may be illustratively the edge illustrated for code 1.

Accordingly, the third stage may output the first edge interpolated signal of the third stage and the second edge interpolated signal of the third stage. An edge of the first edge interpolated signal of the third stage may be located at a designated location of available locations relative to the I signal in the time domain and/or the first edge interpolated signal of the second stage. An edge of the second edge interpolated signal of the third stage may be located at a neighboring available location of the designated location for the first edge interpolated signal of the third stage from available locations in the time domain.

In this illustrative example, the first edge interpolated signal of the third stage and the second edge interpolated signal of the third stage defines a phase slice (or a time difference slice) between codes 0 and 1. Angular resolution of the third stage may be formulated as the following, Φ_{stg3}=Φ_{stg2}/2²=Δθ/2⁹.

Illustratively, in accordance with various aspects described herein, in particular with respect to FIGS. 7-9, an apparatus may include edge interpolator stages described herein, such that the apparatus may further include a buffer between each connection between stages. Illustratively, the apparatus may include a first buffer configured to buffer the first edge interpolated signal of the first stage and a second buffer configured to buffer the second edge interpolated signal of the first stage. Edge interpolators of the second stage, each may be coupled to the first buffer and the second buffer to receive their input signals from the first buffer and the second buffer. Similarly, the apparatus may include a third buffer configured to buffer the first edge interpolated signal of the second stage and a fourth buffer configured to buffer the second edge interpolated signal of the second stage. Edge interpolators of the third stage, each may be coupled to the third buffer and the fourth buffer to receive their input signals from the third buffer and the fourth buffer. Furthermore, the apparatus may receive the phase modulation code from an ADC.

FIG. 9B shows an exemplary illustration of a stage of an apparatus including multiple edge interpolator stages as described herein. It is to be noted that numerical aspects described in FIG. 9A have been illustrated in a manner that first edge interpolated signals of each stage were fixed to the I signal input to the first stage, although the apparatus including multiple edge interpolator stages is configurable changing both first edge interpolated signals and second edge interpolated signals, simultaneously, as desired. In accordance with various aspects provided herein, it may also be desirable to keep one of first edge interpolated signals or second edge interpolated signals fixed in one, more, or all stages, as this may increase the linearity.

In this illustrative example, an edge interpolator 970 of a stage may receive a first signal 972 and a second signal 973, and provide edge interpolation by generating an edge interpolated signal having an edge between an edge of the first signal 972 and an edge on the second signal 973 in time domain based on (a portion of) the phase modulation code 971 that is binary. Illustratively, the stage may further include a first binary to thermometric converter 951 to convert the binary phase modulation code 971 into a unary code to output to a first multiplexer 852 for edge interpolating towards the second signal 973, and a second binary to thermometric converter 961 to convert the binary phase modulation code 971 into a unary code to output to a second multiplexer 862 for edge interpolating towards the first signal 971. In various aspects, a control signal 990 may select one of the first signal 972 or the second signal 973 to be fixed, which is input to select terminals of the multiplexers 952, 962.

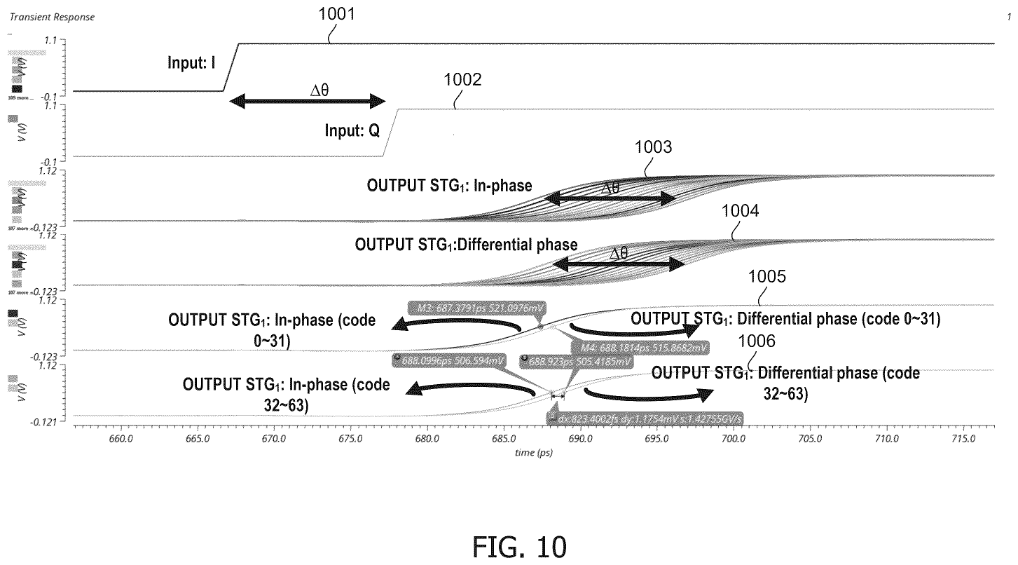

FIG. 10 shows an exemplary graph of a cadence spectre transient simulation for first stage input and output waveshapes. First input signal 1001 and second input signal 1002 have been illustrated with a phase difference of Δθ. 1003 illustrates possible phase configurations of a first edge interpolated signal of the first stage, provided within the range defined by the phase difference of Δθ of input signals 1001, 1002. 1004 illustrates possible phase configurations of a second edge interpolated signal of the first stage, provided within the range defined by the phase difference of Δθ of input signals 1001, 1002. 1005 illustrates two neighboring available phase configurations as representing the first edge interpolated signal and the second edge interpolated signal of the first stage (i.e. between codes 0 and 32). 1006 illustrates two neighboring further available phase configurations as representing the first edge interpolated signal and the second edge interpolated signal of the first stage (i.e. between codes 32 and 64).

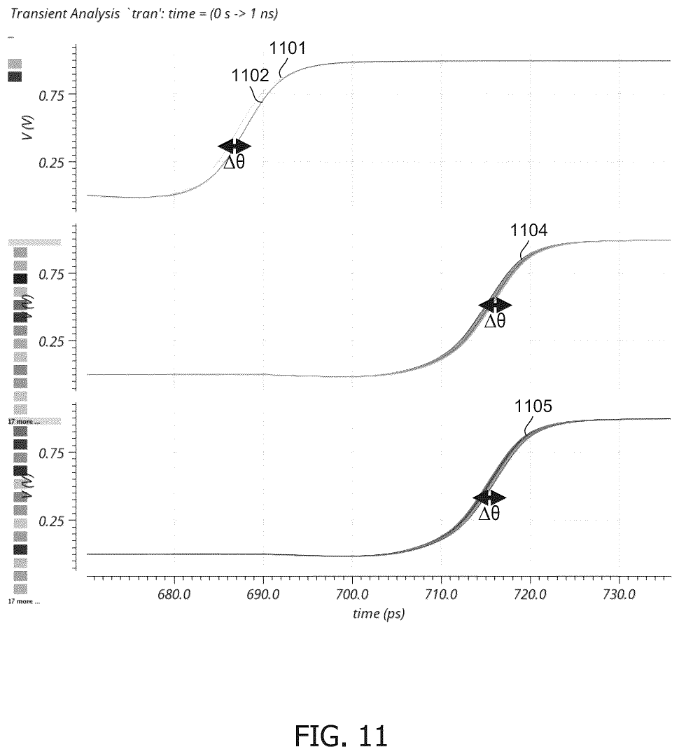

FIG. 11 shows an exemplary graph of a cadence spectre transient simulation for second stage input and output waveshapes. First input signal 1101 (i.e. first edge interpolated signal of the first stage) and second input signal 1102 (i.e. second edge interpolated signal of the first stage) have been illustrated with a phase difference of Δθ. 1104 illustrates possible phase configurations of a first edge interpolated signal of the second stage, provided within the range defined by the phase difference of Δθ of input signals 1101, 1102. 1105 illustrates possible phase configurations of a second edge interpolated signal of the second stage, provided within the range defined by the phase difference of Δθ of input signals 1101, 1102.

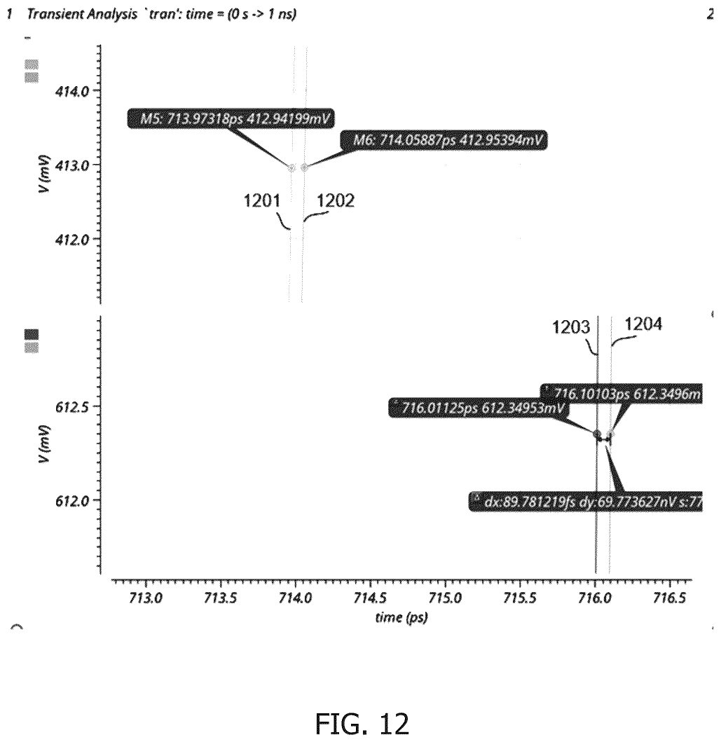

FIG. 12 shows exemplary graph of a cadence spectre transient simulation for second stage input and output waveshapes. 1201 and 1202 illustrate two neighboring available phase configurations as representing the first edge interpolated signal and the second edge interpolated signal of the second stage (i.e. between codes 0 and 4). 1203 and 1204 illustrate a further two neighboring further available phase configurations as representing the first edge interpolated signal and the second edge interpolated signal of the second stage (i.e. between codes 0 and 4).

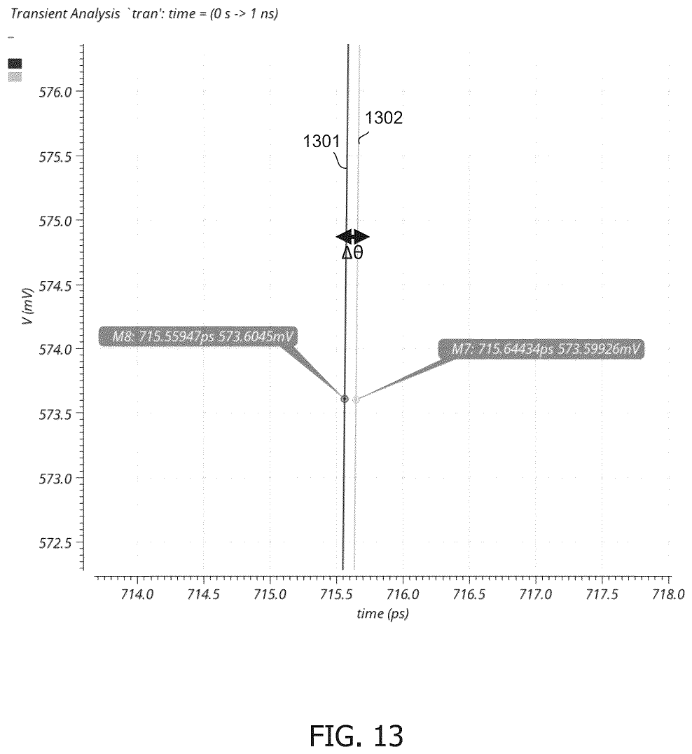

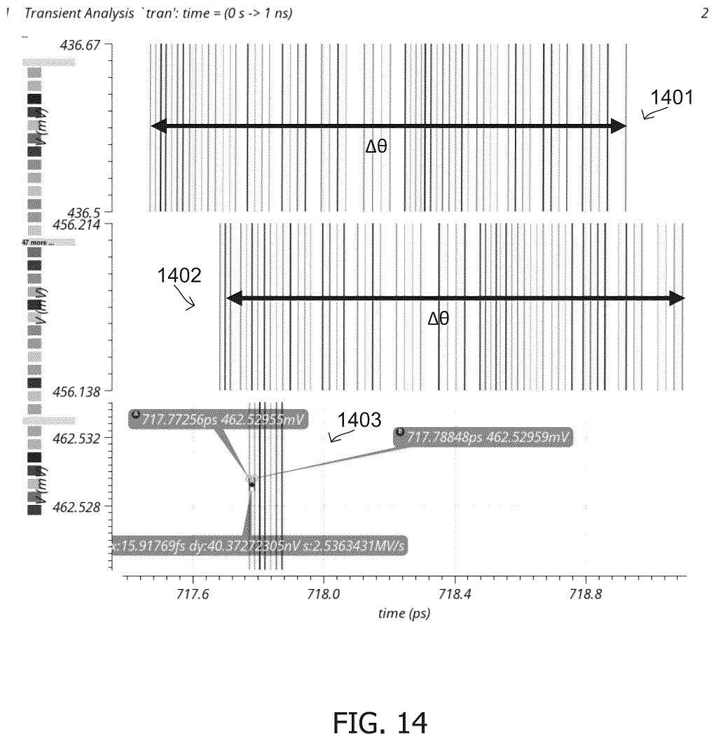

FIG. 13 shows an exemplary graph of a cadence spectre transient simulation for third stage input waveshapes. First input signal 1301 and second input signal 1302 have been illustrated with a phase difference of Δθ. FIG. 14 shows an exemplary graph of a cadence spectre transient simulation for third stage output waveshapes. 1401 illustrates possible phase configurations of a first edge interpolated signal of the third stage, provided within the range defined by the phase difference of Δθ of input signals 1301, 1302. 1402 illustrates possible phase configurations of a second edge interpolated signal of the third stage, provided within the range defined by the phase difference of Δθ of input signals 1301, 1302. Illustratively, all possible phase configurations are defined for codes between 0 and 60 as integers. Illustratively, all possible phase configurations are defined for codes between 0 and 60 as integers. It can be seen from 1403 that a resolution of 16 fs can be illustrated here.

Referring back to the configuration of an apparatus including multiple stages as described in FIG. 7, which may be referred to as 9-b DCEI, it is to be noted that aspects described herein may result in relatively constant DC current drawn irrespective of codeword, in comparison with conventional methods in which DC current is drawn according to the codeword. It is to be noted that the DC current variation in either approach in the proposed method is estimated around 60 times smaller than various conventional methods.

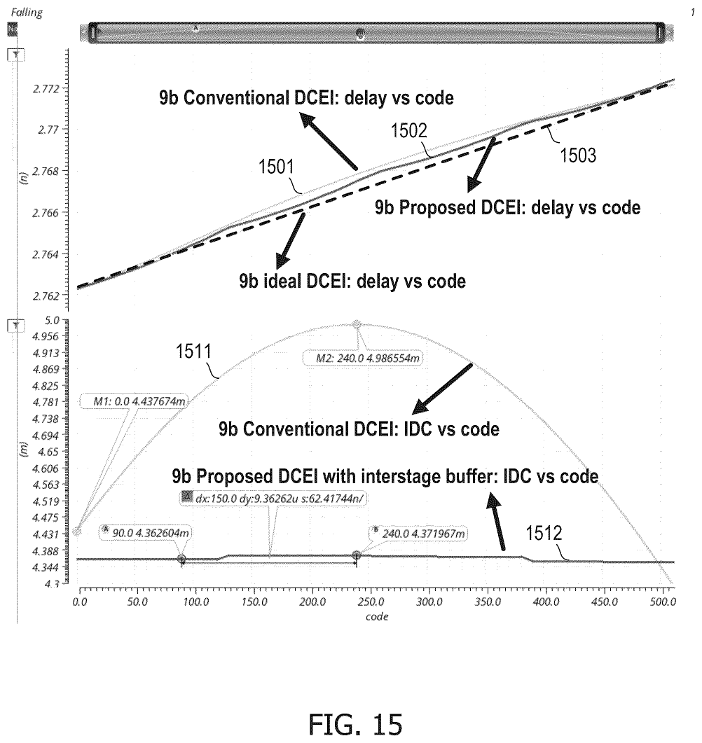

Illustratively, FIG. 15 shows an example of a graph showing simulation results for DC current supply and delay associated with phase modulation code according to the 9-b DCEI configuration illustratively described in FIG. 7 and a conventionally known DCEI. 1501 illustrates delay vs code relationship of the conventionally known DCEI and 1502 illustrates delay vs code relationship of an example of the 9-b DCEI described herein. 1503 illustrates an ideal delay vs code relationship. Further, 1511 illustrates drawn DC current vs code relationship of the conventionally known DCEI and 1512 illustrates drawn DC current vs code relationship of an example of the 9-b DCEI described herein.

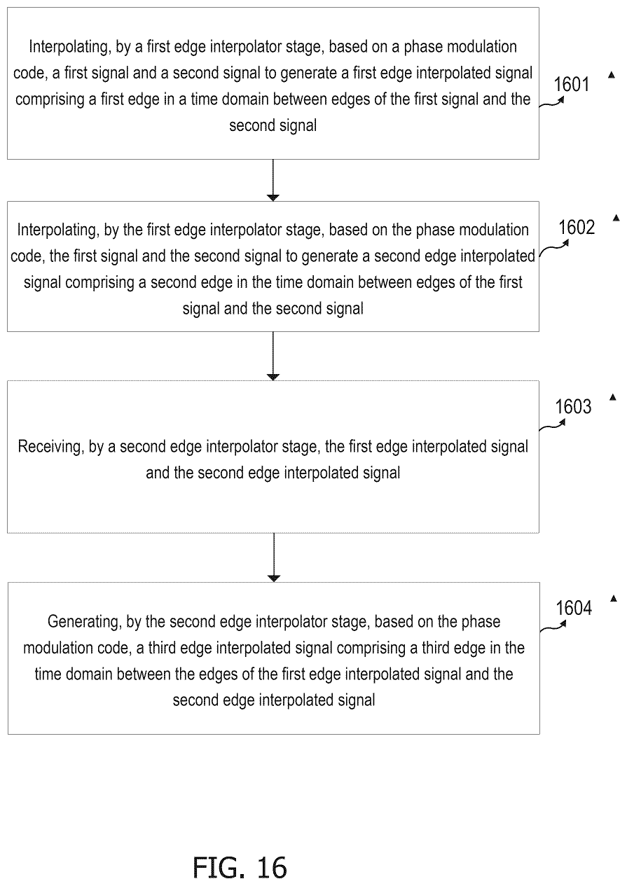

FIG. 16 shows an example of a method. The method may include interpolating 1601, by a first edge interpolator stage, based on a phase modulation code, a first signal and a second signal to generate a first edge interpolated signal comprising a first edge in a time domain between edges of the first signal and the second signal; interpolating 1602, by the first edge interpolator stage, based on the phase modulation code, the first signal and the second signal to generate a second edge interpolated signal comprising a second edge in the time domain between edges of the first signal and the second signal; receiving 1603, by a second edge interpolator stage, the first edge interpolated signal and the second edge interpolated signal; and generating 1604, by the second edge interpolator stage, based on the phase modulation code, a third edge interpolated signal comprising a third edge in the time domain between the edges of the first edge interpolated signal and the second edge interpolated signal. A non-transitory computer-readable medium may include instructions which, if executed by a processor, cause the processor to perform the method.

The following examples pertain to further aspects of this disclosure.

In example 1, the subject matter includes an apparatus including: a first edge interpolator stage including: a first edge interpolator configured to interpolate, based on a phase modulation code, a first signal and a second signal to generate a first edge interpolated signal including a first edge in a time domain between edges of the first signal and the second signal; a second edge interpolator configured to interpolate, based on the phase modulation code, the first signal and the second signal to generate a second edge interpolated signal including a second edge in the time domain between edges of the first signal and the second signal; a second edge interpolator stage configured to: receive the first edge interpolated signal and the second edge interpolated signal; generate, based on the phase modulation code, a third edge interpolated signal including a third edge in the time domain between the edges of the first edge interpolated signal and the second edge interpolated signal.

In example 2, the subject matter of example 1, wherein a time delay between the first edge interpolated signal and the second edge interpolated signal is a first fraction of a time delay between the first signal and the second signal.

In example 3, the subject matter of example 2, wherein the first edge interpolator and the second edge interpolator are configurable to provide a plurality of time delays between the first edge interpolated first signal and the second edge interpolated second signal, each time delay being a corresponding fraction of a time delay a plurality of fractions, wherein the plurality of fractions including the first fraction.

In example 4, the subject matter of example 3, wherein the first fraction is controlled based on the phase modulation code.

In example 5, the subject matter of any one of examples 1 to 4, wherein the first edge interpolator and the second edge interpolator are configured to provide a phase rotation with a fixed phase difference to the first edge interpolated signal and the second edge interpolated signal relative to one of the first signal and the second signal.

In example 6, the subject matter of any one of examples 1 to 5, wherein the first edge interpolator is configurable to provide a number of time delays relative to one of the first signal or the second signal, wherein a time delay difference between two adjacent providable time delays of the number of time delays is fixed.

In example 7, the subject matter of example 6, wherein the second edge interpolator is configurable to provide the number of time delays relative to one of the first signal or the second signal, wherein the time delay difference between two adjacent providable time delays of the number of time delays is fixed.

In example 8, the subject matter of any one of examples 1 to 7, wherein the first edge interpolator and the second edge interpolator are configured to provide a first time delay and a second time delay respectively based on a corresponding unary or binary input code.

In example 9, the subject matter of example 8, wherein the first edge interpolator is configured to provide the first time delay based on a first portion of the phase modulation code; and wherein the second edge interpolator is configured to provide the second time delay based on a bit shifted version of the portion of the phase modulation code to obtain a rotatable phase with a fixed phase difference between the first signal and the second signal.

In example 10, the subject matter of example 9, wherein the first portion of the phase modulation code includes a most significant bit of the phase modulation code.

In example 11, the subject matter of any one of examples 1 to 10, wherein each of the first edge interpolator and the second edge interpolator includes a plurality of edge interpolator cell units respectively, each edge interpolator cell unit of the plurality of edge interpolator cell units is configured to contribute to provision of a unit time delay based on a received input code.

In example 12, the subject matter of any one of examples 1 to 11, wherein the second edge interpolator stage includes a first edge interpolator configured to output, based on a second portion of the phase modulation code, the third edge interpolated signal.

In example 13, the subject matter of example 12, wherein the second edge interpolator stage includes a second edge interpolator configured to output, based on the second portion of the phase modulation code, a fourth edge interpolated signal, wherein a phase difference between edges of the third edge interpolated signal and the fourth edge interpolated signal is based on the time delay between the first edge interpolated signal and the second edge interpolated signal.

In example 14, the subject matter of example 12 or example 13, wherein each of the first edge interpolator of the second edge interpolator stage and the second edge interpolator of the second edge interpolator stage is configurable to provide N different time delays relative to one of the first edge interpolated signal or the second edge interpolated signal in an order; wherein the time delays provided by the first edge interpolator of the second edge interpolator stage and the second edge interpolator of the second edge interpolator stage are subsequent time delays of the N different time delays.

In example 15, the subject matter of any one of examples 12 to 14, may further include one or more subsequent edge interpolator stages; wherein the one or more subsequent edge interpolator stages includes at least a first subsequent edge interpolator stage connected to the second edge interpolator stage to receive the third edge interpolated signal and the fourth edge interpolated signal.

In example 16, the subject matter of example 15, wherein the one or more subsequent edge interpolator stages include further subsequent edge interpolator stages, wherein each further subsequent edge interpolator stage is configured to provide, based on a further portion of the phase modulation code, a time delay between an input time delay between input signals provided by a previous edge interpolator stage of the one or more subsequent edge interpolator stages.

In example 17, the subject matter of any one of examples 1 to 16, may further include one or more buffers including a first buffer configured to buffer the first edge interpolated signal and the second edge interpolated signal, wherein the first buffer is connected between the first edge interpolator stage and the second edge interpolator stage.

In example 18, the subject matter of any one of examples 1 to 17, may further include an output configured to output a phase modulated output signal to a digital power amplifier.

In example 19, the subject matter of example 18, may further include the digital power amplifier configured to output signals based on an amplitude modulation code.

In example 20, the subject matter of example 19, may further include a processor configured to determine code pairs including the phase modulation code and the amplitude modulation code to generate an RF communication signal.

In example 21, the subject matter of any one of examples 1 to 20, wherein a last edge interpolator stage including a single edge interpolator.

In example 22, the subject matter of any one of examples 1 to 20, may further include a last edge interpolator stage including a first last stage edge interpolator and a second last stage edge interpolator.

In example 23, the subject matter includes an apparatus including: a plurality of edge interpolation stages including: a first stage configured to: generate a first edge interpolated signal based on a first signal and a second signal; generate a second edge interpolated signal based on the first signal and the second signal, wherein the first edge interpolated signal and the second edge interpolated signal are generated based on a portion of a phase modulation code associated with the first stage and have a phase difference that is a first fraction of a phase difference between the first signal and the second signal; one or more subsequent stages coupled to the first stage and including a second stage configured to: generate a third edge interpolated signal based on the first edge interpolated signal and the second edge interpolated signal; generate a fourth edge interpolated signal based on the first edge interpolated signal and the second edge interpolated signal, wherein a phase difference between the third edge interpolated signal and the fourth edge interpolated signal is a second fraction of the phase difference between the first edge interpolated signal and the second edge interpolated signal.

In example 24, the subject matter of example 23, may further include a processor configured to provide a respective portion of the phase modulation code to each stage of the plurality of edge interpolation stages.

In example 25, the subject matter of example 24, wherein the respective portion of the phase modulation code provided to the first stage includes a most significant bit of the phase modulation code and the respective portion of the phase modulation code provided to a last stage of the one or more subsequent stages includes a least significant bit of the phase modulation code.

In example 26, the subject matter of any one of examples 24 to 25, wherein each stage of the plurality of edge interpolation stages includes a first edge interpolator and a second edge interpolator configured to receive the same input signals.

In example 27, the subject matter of any one of examples 24 to 26, wherein the first edge interpolator of each stage is configured to provide a corresponding phase difference based on the respective portion of the phase modulation code; wherein the second edge interpolator of each stage is configured to provide a corresponding phase difference based on a bit shifted version of the respective portion of the phase modulation code.

In example 28, the subject matter of any one of examples 24 to 27, wherein each of the first edge interpolator and the second edge interpolator includes a number of edge interpolator cell units; wherein a number of bits corresponding to each portion of the phase modulation code provided to a respective stage of the plurality of edge interpolation stages is proportional to the respective number of edge interpolator cell units of the respective stage.

In example 29, the subject matter of any one of examples 24 to 28, wherein each stage of the one or more subsequent stages are coupled to each other in a cascade configuration, each stage configured to provide a corresponding phase difference between corresponding input signals received from a previous stage of the one or more subsequent stages and output corresponding output signals to a next stage of the one or more subsequent stages.

In example 30, the subject matter includes an apparatus including: a first edge interpolator stage including: a first means for interpolating, based on a phase modulation code, a first signal and a second signal to generate a first edge interpolated signal including a first edge in a time domain between edges of the first signal and the second signal; a second means for interpolating, based on the phase modulation code, the first signal and the second signal to generate a second edge interpolated signal including a second edge in the time domain between edges of the first signal and the second signal; a second edge interpolator stage including: means for receiving the first edge interpolated signal and the second edge interpolated signal; means for generating, based on the phase modulation code, a third edge interpolated signal including a third edge in the time domain between the edges of the first edge interpolated signal and the second edge interpolated signal.

In example 31, the subject matter of example 30, wherein a time delay between the first edge interpolated signal and the second edge interpolated signal is a first fraction of a time delay between the first signal and the second signal.

In example 32, the subject matter of example 31, wherein the first means and the second means are configurable to provide a plurality of time delays between the first edge interpolated first signal and the second edge interpolated second signal, each time delay being a corresponding fraction of a time delay a plurality of fractions, wherein the plurality of fractions including the first fraction.

In example 33, the subject matter of example 32, wherein the first fraction is controlled based on the phase modulation code.

In example 34, the subject matter of any one of examples 30 to 33, wherein the first means and the second means include a means for providing a phase rotation with a fixed phase difference to the first edge interpolated signal and the second edge interpolated signal relative to one of the first signal and the second signal.

In example 35, the subject matter of any one of examples 30 to 34, wherein the first means is configurable to provide a number of time delays relative to one of the first signal or the second signal, wherein a time delay difference between two adjacent providable time delays of the number of time delays is fixed.

In example 36, the subject matter of example 35, wherein the second means is configurable to provide the number of time delays relative to one of the first signal or the second signal, wherein the time delay difference between two adjacent providable time delays of the number of time delays is fixed.

In example 37, the subject matter of any one of examples 30 to 36, wherein the first means and the second means further include a means for providing a first time delay and a second time delay respectively based on a corresponding unary or binary input code.

In example 38, the subject matter of example 37, wherein the first means includes a means for providing the first time delay based on a first portion of the phase modulation code; and wherein the second means includes a means for providing the second time delay based on a bit shifted version of the portion of the phase modulation code to obtain a rotatable phase with a fixed phase difference between the first signal and the second signal.

In example 39, the subject matter of example 38, wherein the first portion of the phase modulation code includes a most significant bit of the phase modulation code.

In example 40, the subject matter of any one of examples 30 to 39, wherein each of the first means and the second means include a plurality of edge interpolator cell units respectively, each edge interpolator cell unit of the plurality of edge interpolator cell units is configured to contribute to provision of a unit time delay based on a received input code.

In example 41, the subject matter of any one of examples 30 to 40, wherein the second edge interpolator stage includes a first means for outputting, based on a second portion of the phase modulation code, the third edge interpolated signal.

In example 42, the subject matter of example 41, wherein the second edge interpolator stage includes a second means for outputting, based on the second portion of the phase modulation code, a fourth edge interpolated signal, wherein a phase difference between edges of the third edge interpolated signal and the fourth edge interpolated signal is based on the time delay between the first edge interpolated signal and the second edge interpolated signal.

In example 43, the subject matter of example 41 or example 42, wherein each of the first means of the second edge interpolator stage and the second means of the second edge interpolator stage is configurable to provide N different time delays relative to one of the first edge interpolated signal or the second edge interpolated signal in an order; wherein the time delays provided by the first means of the second edge interpolator stage and the second means of the second edge interpolator stage are subsequent time delays of the N different time delays.

In example 44, the subject matter of any one of examples 41 to 43, may further include one or more subsequent edge interpolator stages; wherein the one or more subsequent edge interpolator stages includes at least a first subsequent edge interpolator stage connected to the second edge interpolator stage to receive the third edge interpolated signal and the fourth edge interpolated signal.

In example 45, the subject matter of example 44, wherein the one or more subsequent edge interpolator stages include further subsequent means, wherein each further subsequent means for providing, based on a further portion of the phase modulation code, a time delay between an input time delay between input signals provided by a previous edge interpolator stage of the one or more subsequent edge interpolator stages.

In example 46, the subject matter of any one of examples 30 to 45, may further include one or more buffers including a first buffer configured to buffer the first edge interpolated signal and the second edge interpolated signal, wherein the first buffer is connected between the first edge interpolator stage and the second edge interpolator stage.

In example 47, the subject matter of any one of examples 30 to 46, may further include an output configured to output a phase modulated output signal to a digital power amplifier.

In example 48, the subject matter of example 47, may further include the digital power amplifier configured to output signals based on an amplitude modulation code.

In example 49, the subject matter of example 48, may further include a processor configured to determine code pairs including the phase modulation code and the amplitude modulation code to generate an RF communication signal.

In example 50, the subject matter includes an apparatus including: a plurality of edge interpolation stages including: a first stage including: a means for generating a first edge interpolated signal based on a first signal and a second signal; a means for generating a second edge interpolated signal based on the first signal and the second signal, wherein the first edge interpolated signal and the second edge interpolated signal are generated based on a portion of a phase modulation code associated with the first stage and have a phase difference that is a first fraction of a phase difference between the first signal and the second signal; one or more subsequent stages coupled to the first stage and including a second stage including: a means for generating a third edge interpolated signal based on the first edge interpolated signal and the second edge interpolated signal; a means for generating a fourth edge interpolated signal based on the first edge interpolated signal and the second edge interpolated signal, wherein a phase difference between the third edge interpolated signal and the fourth edge interpolated signal is a second fraction of the phase difference between the first edge interpolated signal and the second edge interpolated signal.

In example 51, the subject matter of example 50, may further include a processing means for providing a respective portion of the phase modulation code to each stage of the plurality of edge interpolation stages.

In example 52, the subject matter of example 51, wherein the respective portion of the phase modulation code provided to the first stage includes a most significant bit of the phase modulation code and the respective portion of the phase modulation code provided to a last stage of the one or more subsequent stages includes a least significant bit of the phase modulation code.

In example 53, the subject matter of any one of examples 51 to 52, wherein each stage of the plurality of edge interpolation stages includes a first edge interpolator and a second edge interpolator configured to receive the same input signals.

In example 54, the subject matter of any one of examples 51 to 53, wherein the first edge interpolator of each stage is configured to provide a corresponding phase difference based on the respective portion of the phase modulation code; wherein the second edge interpolator of each stage is configured to provide a corresponding phase difference based on a bit shifted version of the respective portion of the phase modulation code.

In example 55, the subject matter of any one of examples 51 to 54, wherein each of the first edge interpolator and the second edge interpolator includes a number of edge interpolator cell units; wherein a number of bits corresponding to each portion of the phase modulation code provided to a respective stage of the plurality of edge interpolation stages is proportional to the respective number of edge interpolator cell units of the respective stage.

In example 56, the subject matter of any one of examples 51 to 55, wherein each stage of the one or more subsequent stages are coupled to each other in a cascade configuration, each stage configured to provide a corresponding phase difference between corresponding input signals received from a previous stage of the one or more subsequent stages and output corresponding output signals to a next stage of the one or more subsequent stages.

In example 57, a method including: interpolating, by a first edge interpolator stage, based on a phase modulation code, a first signal and a second signal to generate a first edge interpolated signal including a first edge in a time domain between edges of the first signal and the second signal; interpolating, by the first edge interpolator stage, based on the phase modulation code, the first signal and the second signal to generate a second edge interpolated signal including a second edge in the time domain between edges of the first signal and the second signal; receiving, by a second edge interpolator stage, the first edge interpolated signal and the second edge interpolated signal; generating, by the second edge interpolator stage, based on the phase modulation code, a third edge interpolated signal including a third edge in the time domain between the edges of the first edge interpolated signal and the second edge interpolated signal.

In example 58, the method of example 57, wherein the method further includes any of the aspects described in this disclosure.

The word “exemplary” is used herein to mean “serving as an example, instance, or illustration”. Any embodiment or design described herein as “exemplary” is not necessarily to be construed as preferred or advantageous over other embodiments or designs.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in plural form that does not expressly state “plurality” or “multiple” likewise refers to a quantity equal to or greater than one.

Any vector and/or matrix notation utilized herein is exemplary in nature and is employed solely for purposes of explanation. Accordingly, the apparatuses and methods of this disclosure accompanied by vector and/or matrix notation are not limited to being implemented solely using vectors and/or matrices, and that the associated processes and computations may be equivalently performed with respect to sets, sequences, groups, etc., of data, observations, information, signals, samples, symbols, elements, etc.

As used herein, “memory” is understood as a non-transitory computer-readable medium in which data or information can be stored for retrieval. References to “memory” included herein may thus be understood as referring to volatile or non-volatile memory, including random access memory (“RAM”), read-only memory (“ROM”), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

The term “software” refers to any type of executable instruction, including firmware.

In the context of this disclosure, the term “process” may be used, for example, to indicate a method. Illustratively, any process described herein may be implemented as a method (e.g., a channel estimation process may be understood as a channel estimation method). Any process described herein may be implemented as a non-transitory computer readable medium including instructions configured, when executed, to cause one or more processors to carry out the process (e.g., to carry out the method).

Throughout the drawings, it should be noted that like reference numbers are used to depict the same or similar elements, features, and structures, unless otherwise noted. It should be noted that certain components may be omitted for the sake of simplicity. It should be noted that nodes (dots) are provided to identify the circuit line intersections in the drawings including electronic circuit diagrams.

The phrase “at least one” and “one or more” may be understood to include a numerical quantity greater than or equal to one (e.g., one, two, three, four, [. . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [. . . ], etc.).

As used herein, a signal or information that is “indicative of”, “representative”, “representing”, or “indicating” a value or other information may be a digital or analog signal that encodes or otherwise, communicates the value or other information in a manner that can be decoded by and/or cause a responsive action in a component receiving the signal. The signal may be stored or buffered in computer-readable storage medium prior to its receipt by the receiving component and the receiving component may retrieve the signal from the storage medium. Further, a “value” that is “indicative of” or “representative” some quantity, state, or parameter may be physically embodied as a digital signal, an analog signal, or stored bits that encode or otherwise communicate the value.

As used herein the term “phase” may refer to a position of a point in time on a signal or waveform cycle relative to a reference point. It indicates the status or position of the signal or waveform at a specific moment, which may be referred to in degrees or radians. In various aspects described herein, the reference point may be the in-phase, or I, signal unless indicated otherwise. In a related manner, the term “phase difference” may refer to a comparison of the phase of one signal or waveform to another, describing the relative alignment or displacement between two waveforms. Again, within the same context, the “time difference” may refer to the temporal separation between two events or points on a waveform or signal. It represents the duration or time interval between these events, such as edges. In some aspects, both “time difference” and “phase difference” may be used to describe aspects from different perspectives.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The terms “one or more processors” is intended to refer to a processor or a controller. The one or more processors may include one processor or a plurality of processors. The terms are simply used as an alternative to the “processor” or “controller”.

The term “user device” is intended to refer to a device of a user (e.g. occupant) that may be configured to provide information related to the user. The user device may exemplarily include a mobile phone, a smart phone, a wearable device (e.g. smart watch, smart wristband), a computer, etc.

As utilized herein, terms “module”, “component,” “system,” “circuit,” “element,” “slice,” “circuit,” and the like are intended to refer to a set of one or more electronic components, a computer-related entity, hardware, software (e.g., in execution), and/or firmware. For example, circuit or a similar term can be a processor, a process running on a processor, a controller, an object, an executable program, a storage device, and/or a computer with a processing device. By way of illustration, an application running on a server and the server can also be circuit. One or more circuits can reside within the same circuit, and circuit can be localized on one computer and/or distributed between two or more computers. A set of elements or a set of other circuits can be described herein, in which the term “set” can be interpreted as “one or more”.

The terminology in accordance with open-RAN (O-RAN) specifications is to be considered for Radio Units (RUs), Distributed Units (DUs) and Centralized Units (CUs). Inherently, a base station is considered to be disaggregated into such units in accordance with layers of a corresponding protocol stack into these logical nodes, which all of them can be implemented by the same device or multiple devices in which each device may be deployed with one of these units.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art. The term “data item” may include data or a portion of data.

It will be understood that when an element is referred to as being “connected” or “coupled” to another element, it can be physically connected or coupled to the other element such that current and/or electromagnetic radiation (e.g., a signal) can flow along a conductive path formed by the elements. Inherently, such element is connectable or couplable to the another element. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “provided” to an element, the voltage, current, or signal may be conducted to the element by way of a physical connection or by way of capacitive, electro-magnetic, or inductive coupling that does not involve a physical connection.

Unless explicitly specified, the term “instance of time” refers to a time of a particular event or situation according to the context. The instance of time may refer to an instantaneous point in time, or to a period of time which the particular event or situation relates to.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

An antenna port may be understood as a logical concept representing a specific channel or associated with a specific channel. An antenna port may be understood as a logical structure associated with a respective channel (e.g., a respective channel between a user equipment and a base station). Illustratively, symbols (e.g., OFDM symbols) transmitted over an antenna port (e.g., over a first channel) may be subject to different propagation conditions with respect to other symbols transmitted over another antenna port (e.g., over a second channel).

While the above descriptions and connected figures may depict electronic device components as separate elements, skilled persons will appreciate the various possibilities to combine or integrate discrete elements into a single element. Such may include combining two or more circuits to form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method. All acronyms defined in the above description additionally hold in all claims included herein.

What is claimed is:

1. An apparatus comprising:
a first edge interpolator stage comprising:
a first edge interpolator configured to interpolate, based on a phase modulation code, a first signal and a second signal to generate a first edge interpolated signal comprising a first edge in a time domain between edges of the first signal and the second signal;
a second edge interpolator configured to interpolate, based on the phase modulation code, the first signal and the second signal to generate a second edge interpolated signal comprising a second edge in the time domain between edges of the first signal and the second signal;
a second edge interpolator stage configured to:
receive the first edge interpolated signal and the second edge interpolated signal; and
generate, based on the phase modulation code, a third edge interpolated signal comprising a third edge in the time domain between the edges of the first edge interpolated signal and the second edge interpolated signal.

2. The apparatus of claim 1,
wherein a time delay between the first edge interpolated signal and the second edge interpolated signal is a first fraction of a time delay between the first signal and the second signal.

3. The apparatus of claim 2,
wherein the first edge interpolator and the second edge interpolator are configurable to provide a plurality of time delays between the first edge interpolated first signal and the second edge interpolated second signal, each time delay being a corresponding fraction of a time delay a plurality of fractions, wherein the plurality of fractions comprising the first fraction.

4. The apparatus of claim 3,
wherein the first fraction is controlled based on the phase modulation code.

5. The apparatus of claim 1,
wherein the first edge interpolator and the second edge interpolator are configured to provide a phase rotation with a fixed phase difference to the first edge interpolated signal and the second edge interpolated signal relative to one of the first signal and the second signal.

6. The apparatus of claim 1,
wherein the first edge interpolator is configurable to provide a number of time delays relative to one of the first signal or the second signal, wherein a time delay difference between two adjacent providable time delays of the number of time delays is fixed.

7. The apparatus of claim 6,
wherein the second edge interpolator is configurable to provide the number of time delays relative to one of the first signal or the second signal, wherein the time delay difference between two adjacent providable time delays of the number of time delays is fixed.

8. The apparatus of claim 1,
wherein the first edge interpolator and the second edge interpolator are configured to provide a first time delay and a second time delay respectively based on a corresponding unary or binary input code.

9. The apparatus of claim 8,
wherein the first edge interpolator is configured to provide the first time delay based on a first portion of the phase modulation code; and
wherein the second edge interpolator is configured to provide the second time delay based on a bit shifted version of the portion of the phase modulation code to obtain a rotatable phase with a fixed phase difference between the first signal and the second signal.

10. The apparatus of claim 9,
wherein the first portion of the phase modulation code comprises a most significant bit of the phase modulation code.

11. The apparatus of claim 1,
wherein each of the first edge interpolator and the second edge interpolator comprises a plurality of edge interpolator cell units respectively, each edge interpolator cell unit of the plurality of edge interpolator cell units is configured to contribute to provision of a unit time delay based on a received input code.

12. The apparatus of claim 1,
wherein the second edge interpolator stage comprises a first edge interpolator configured to output, based on a second portion of the phase modulation code, the third edge interpolated signal.

13. The apparatus of claim 12,
wherein the second edge interpolator stage comprises a second edge interpolator configured to output, based on the second portion of the phase modulation code, a fourth edge interpolated signal, wherein a phase difference between edges of the third edge interpolated signal and the fourth edge interpolated signal is based on the time delay between the first edge interpolated signal and the second edge interpolated signal.

14. The apparatus of claim 1,
further comprising one or more buffers comprising a first buffer configured to buffer the first edge interpolated signal and the second edge interpolated signal, wherein the first buffer is connected between the first edge interpolator stage and the second edge interpolator stage.

15. The apparatus of claim 1,
further comprising an output configured to output a phase modulated output signal to a digital power amplifier.

16. The apparatus of claim 15,
further comprising the digital power amplifier configured to output signals based on an amplitude modulation code.

17. The apparatus of claim 16,
further comprising a processor configured to determine code pairs including the phase modulation code and the amplitude modulation code to generate an RF communication signal.

18. An apparatus comprising:
a plurality of edge interpolation stages comprising:
a first stage configured to:
generate a first edge interpolated signal based on a first signal and a second signal;
generate a second edge interpolated signal based on the first signal and the second signal, wherein the first edge interpolated signal and the second edge interpolated signal are generated based on a portion of a phase modulation code associated with the first stage and have a phase difference that is a first fraction of a phase difference between the first signal and the second signal;
one or more subsequent stages coupled to the first stage and comprising a second stage configured to:
generate a third edge interpolated signal based on the first edge interpolated signal and the second edge interpolated signal; and
generate a fourth edge interpolated signal based on the first edge interpolated signal and the second edge interpolated signal, wherein a phase difference between the third edge interpolated signal and the fourth edge interpolated signal is a second fraction of the phase difference between the first edge interpolated signal and the second edge interpolated signal.

19. The apparatus of claim 18,
further comprising a processor configured to provide a respective portion of the phase modulation code to each stage of the plurality of edge interpolation stages.

20. The apparatus of claim 18,
wherein each stage of the plurality of edge interpolation stages comprises a first edge interpolator and a second edge interpolator configured to receive the same input signals.
